(19) United States
(12) Patent Application Publication
(10) Pub. No.: US 2016/0307845 A1
(43) Pub. Date: Oct. 20, 2016

(54) SEMICONDUCTOR DEVICE AND METHOD OF MANUFACTURING THE SAME

(71) Applicant: RENESAS ELECTRONICS CORPORATION, Tokyo (JP)

(72) Inventor: Takahisa FURUHASHI, Tokyo (JP)

(21) Appl. No.: 15/077,741

(22) Filed: Mar. 22, 2016

(30) Foreign Application Priority Data
Apr. 16, 2015 (JP) 2015-084470

(51) Int. Cl. H01L 23/528; H01L 21/768; H01L 23/532

(52) U.S. Cl. CPC H01L 23/5283; H01L 23/5329; H01L 21/76802; H01L 21/76846; H01L 21/76879

(57) ABSTRACT

An object of the invention is to provide a semiconductor device with buried copper wirings having improved reliability. An interlayer insulating film including a porous Low-k film has, in a wiring trench thereof, a wiring. The wiring has a first barrier conductor film formed on the bottom surface and the side wall of the wiring trench, a second barrier conductor film formed on the first barrier conductor film, and a main conductor film formed on the second barrier conductor film and comprised mainly of copper. The first barrier conductor film and the second barrier conductor film are made of the same conductor material but the first conductor film has a density lower than that of the second barrier conductor film.

### CROSS-REFERENCE TO RELATED APPLICATIONS

The disclosure of Japanese Patent Application No. 2015-084470 filed on Apr. 16, 2015 including the specification, drawings, and abstract is incorporated herein by reference in its entirety.

### BACKGROUND

The present invention relates to a semiconductor device and a method of manufacturing the same, which can be used preferably for, for example, a semiconductor device having a buried copper wiring and method of manufacturing the semiconductor device.

Elements of a semiconductor device are coupled, for example, by a multilayer wiring structure, by which a circuit is formed. One of wiring structures is a buried wiring structure. The buried wiring structure is formed by filling a wiring opening such as wiring trench or hole formed in an insulating film with a wiring material by the damascene technology.

Japanese Unexamined Patent Application Publication No. 2006-190884 (Patent Document 1), Japanese Unexamined Patent Application Publication No. 2004-253781 (Patent Document 2), Japanese Unexamined Patent Application Publication No. 2009-158543 (Patent Document 3), Japanese Unexamined Patent Application Publication No. 2010-87352 (Patent Document 4), Japanese Unexamined Patent Application Publication No. 2004-94274 (Patent Document 5), and Japanese Unexamined Patent Application Publication No. 2009-4633 (Patent Document 6) describe a technology relating to buried wirings. Japanese Unexamined Patent Application Publication No. Hei 6(1994)-151815 (Patent Document 7) describes a technology relating to an aluminum-based wiring. Japanese Unexamined Patent Application Publication No. 2011-142169 (Patent Document 8), Japanese Unexamined Patent Application Publication No. 2011-9642 (Patent Document 9), Japanese Unexamined Patent Application Publication No. 2008-60316 (Patent Document 10), and Japanese Unexamined Patent Application Publication No. 2007-43018 (Patent Document 11) describe a technology relating to buried wirings.

### PATENT DOCUMENTS

[Patent Document 1] Japanese Unexamined Patent Application Publication No. 2006-190884

[Patent Document 2] Japanese Unexamined Patent Application Publication No. 2004-253781

[Patent Document 3] Japanese Unexamined Patent Application Publication No. 2009-158543

[Patent Document 4] Japanese Unexamined Patent Application Publication No. 2010-87352

[Patent Document 5] Japanese Unexamined Patent Application Publication No. 2004-94274

[Patent Document 6] Japanese Unexamined Patent Application Publication No. 2009-4633

[Patent Document 7] Japanese Unexamined Patent Application Publication No. Hei 6(1994)-151815

[Patent Document 8] Japanese Unexamined Patent Application Publication No. 2011-142169

[Patent Document 9] Japanese Unexamined Patent Application Publication No. 2011-9642

[Patent Document 10] Japanese Unexamined Patent Application Publication No. 2008-60316

[Patent Document 11] Japanese Unexamined Patent Application Publication No. 2007-43018

### SUMMARY

Even a semiconductor device having a buried copper wiring is desired to have more improved reliability.

Another object and novel features will be apparent by the description herein and accompanying drawings.

According to one embodiment, a semiconductor device has a wiring buried in a wiring trench in an interlayer insulating film. The wiring has a first barrier conductor film formed on the bottom surface and side wall of the wiring trench, a second barrier conductor film formed on the first barrier conductor film, and a main conductor film formed on the second barrier conductor film. The interlayer insulating film includes a porous low-dielectric-constant insulating film. The main conductor film is comprised mainly of copper, while the first barrier conductor film and the second barrier conductor film are made of the same conductor material. The first barrier conductor film has a density lower than that of the second barrier conductor film.

According to another embodiment, manufacturing steps of a semiconductor device include (a) a step of forming an interlayer insulating film including a porous low-dielectric-constant insulating film and (b) a step of forming a wiring trench in the interlayer insulating film. The manufacturing steps further include (c) a step of forming a first barrier conductor film on the interlayer insulating film including the bottom surface and side surface of the wiring trench, (d) a step of forming a second barrier conductor film on the first barrier conductor film, and (e) a step of forming, on the second barrier conductor film, a main conductor film comprised mainly of copper so as to fill the wiring trench therewith. The manufacturing steps further include (f) a step of forming a wiring buried in the wiring trench by removing the main conductor film, the second barrier conductor film, and the first barrier conductor film outside the wiring trench and leaving the main conductor film, the second barrier conductor film, and the first barrier conductor film in the wiring trench. The first barrier conductor film and the second barrier conductor film are made of the same conductor material. The first barrier conductor film has a density lower than that of the second barrier conductor film.

According to the above embodiments, a semiconductor device having improved reliability can be provided.

### BRIEF DESCRIPTION OF THE DRAWINGS

FIG. 1 is a fragmentary cross-sectional view of a semiconductor device of First Embodiment;

FIG. 2 is a fragmentary cross-sectional view of the semiconductor device of First Embodiment during a manufacturing step thereof;

FIG. 3 is a fragmentary cross-sectional view of the semiconductor device during a manufacturing step following that of FIG. 2;

FIG. 4 is a fragmentary cross-sectional view of the semiconductor device during a manufacturing step following that of FIG. 3;

FIG. 5 is a fragmentary cross-sectional view of the semiconductor device during a manufacturing step following that of FIG. 4;

FIG. 6 is a fragmentary cross-sectional view of the semiconductor device during a manufacturing step following that of FIG. 5;

FIG. 7 is a fragmentary cross-sectional view of the semiconductor device during a manufacturing step following that of FIG. 6;

FIG. 8 is a fragmentary cross-sectional view of the semiconductor device during a manufacturing step following that of FIG. 7;

FIG. 9 is a fragmentary cross-sectional view of the semiconductor device during a manufacturing step following that of FIG. 8;

FIG. 10 is a fragmentary cross-sectional view of the semiconductor device during a manufacturing step following that of FIG. 9;

FIG. 11 is a fragmentary cross-sectional view of the semiconductor device during a manufacturing step following that of FIG. 10;

FIG. 12 is a fragmentary cross-sectional view of the semiconductor device during a manufacturing step following that of FIG. 11;

FIG. 13 is a fragmentary cross-sectional view of the semiconductor device during a manufacturing step following that of FIG. 12;

FIG. 14 is a fragmentary cross-sectional view of the semiconductor device during a manufacturing step following that of FIG. 13;

FIG. 15 is a fragmentary cross-sectional view of the semiconductor device during a manufacturing step following that of FIG. 14;

FIG. 16 is a fragmentary cross-sectional view of the semiconductor device during a manufacturing step following that of FIG. 15;

FIG. 17 is a fragmentary cross-sectional view of the semiconductor device during a manufacturing step following that of FIG. 16;

FIG. 18 is a fragmentary cross-sectional view of the semiconductor device during a manufacturing step following that of FIG. 17;

FIG. 19 is a fragmentary cross-sectional view of the semiconductor device during a manufacturing step following that of FIG. 18;

FIG. 20 is a fragmentary cross-sectional view of the semiconductor device during a manufacturing step following that of FIG. 19;

FIG. 21 is a fragmentary cross-sectional view of the semiconductor device during a manufacturing step following that of FIG. 20;

FIG. 22 is a fragmentary cross-sectional view of the semiconductor device during a manufacturing step following that of FIG. 21;

FIG. 23 is a fragmentary cross-sectional view of the semiconductor device during a manufacturing step following that of FIG. 22;

FIG. 24 is a fragmentary cross-sectional view of the semiconductor device during a manufacturing step following that of FIG. 23;

FIG. 25 is a fragmentary cross-sectional view of a semiconductor device of First Investigation Example;

FIG. 26 is a fragmentary cross-sectional view of a semiconductor device of Second Investigation Example;

FIG. 27 is an explanatory view showing one example of a sputtering apparatus to be used for the formation of a barrier conductor film;

FIG. 28 is a fragmentary cross-sectional view of a semiconductor device of Second Embodiment;

FIG. 29 is a fragmentary cross-sectional view of the semiconductor device of Second Embodiment during a manufacturing step thereof;

FIG. 30 is a fragmentary cross-sectional view of the semiconductor device during a manufacturing step following that of FIG. 29;

FIG. 31 is a fragmentary cross-sectional view of the semiconductor device during a manufacturing step following that of FIG. 30;

FIG. 32 is a fragmentary cross-sectional view of the semiconductor device during a manufacturing step following that of FIG. 31;

FIG. 33 is a fragmentary cross-sectional view of the semiconductor device during a manufacturing step following that of FIG. 32;

FIG. 34 is a fragmentary cross-sectional view of the semiconductor device during a manufacturing step following that of FIG. 33;

FIG. 35 is a fragmentary cross-sectional view of the semiconductor device during a manufacturing step following that of FIG. 34;

FIG. 36 is a fragmentary cross-sectional view of the semiconductor device during a manufacturing step following that of FIG. 35; and

FIG. 37 is a fragmentary cross-sectional view of the semiconductor device during a manufacturing step following that of FIG. 36.

### DETAILED DESCRIPTION

In the following embodiments, a description will be made after divided into a plurality of sections or embodiments if necessary for the sake of convenience. These sections or embodiments are not independent from each other unless otherwise particularly specified, but one of them may be a modification example, details, complementary description, or the like of a part or whole of the other one. In the following embodiments, when a reference is made to the number (including the number, value, amount, range, or the like) of a component, the number is not limited to a specific number but may be more or less than the specific number, unless otherwise particularly specified or principally apparent that the number is limited to the specific number. Further, in the following embodiments, it is needless to say that the constituent component (including component step or the like) is not always essential unless otherwise particularly specified or principally apparent that it is essential. Similarly, in the following embodiments, when a reference is made to the shape, positional relationship, or the like of the constituent component, that substantially approximate or analogous to it is also embraced unless otherwise particularly specified or principally apparent that it is not. This also applies to the above-mentioned value, range, or the like.

The embodiments will hereinafter be described based on drawings. In all the drawings for describing the embodiments, members having the same function will be identified by the same reference numerals and overlapping descriptions will be omitted. In the following embodiments, a description on the same or similar portions is not repeated in principle unless otherwise particularly necessary.

In the drawings to be used in the following embodiments, even a cross-sectional view is sometimes not hatched to make it easier to understand. Even a plan view may be hatched to make it easier to understand.

### First Embodiment

### Structure of Semiconductor Device

The semiconductor device of the present embodiment will be described referring to drawings. The semiconductor device of the present embodiment has a buried copper wiring.

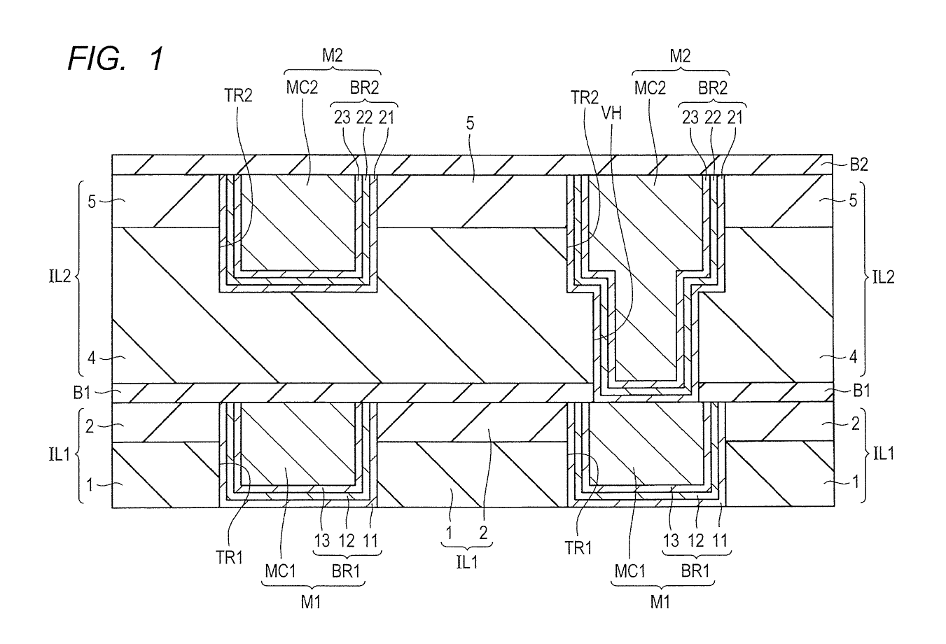

FIG. 1 is a fragmentary cross-sectional view of the semiconductor device of the present embodiment.

FIG. 1 omits therefrom the structure of layers below a wiring layer having therein a wiring M1 and also the structure of layers above a barrier insulating film B2 in order to simplify the drawing.

The semiconductor device of the present embodiment has a wiring structure (multilayer wiring structure) having a plurality of wiring layers on a semiconductor substrate (corresponding to a semiconductor substrate SB which will be described later) and has, as the wiring structure, a buried copper wiring.

The semiconductor device of the present embodiment will hereinafter be described specifically referring to FIG. 1.

The semiconductor device of the present embodiment has a semiconductor substrate (corresponding to a semiconductor substrate SB which will be described later) and a wiring structure formed on the semiconductor substrate (SB) and having a plurality of wiring layers. This wiring structure includes an interlayer insulating film IL1, a wiring M1 buried in the interlayer insulating film IL1, a barrier insulating film B1 formed on the interlayer insulating film IL1 so as to cover the wiring M1, an interlayer insulating film IL2 formed on the barrier insulating film B1, a wiring M2 buried in the interlayer insulating film IL2, and a barrier insulating film B2 formed on the interlayer insulating film IL2 so as to cover the wiring M2.

This means that the semiconductor device of the present embodiment has the interlayer insulating film IL1 formed over the semiconductor substrate (corresponding to a semiconductor substrate SB which will be described later), the wiring M1 buried in the interlayer insulating film IL1, the barrier insulating film B1 formed on the interlayer insulating film IL1 so as to cover the wiring M1, the interlayer insulating film IL2 formed on the barrier insulating film B1, and the wiring M2 buried in the interlayer insulating film IL2.

The interlayer insulating film IL2 has thereon the barrier insulating film B2 so as to cover the wiring M2. The barrier insulating film B2 can have thereon another interlayer insulating film or wiring, but illustration and description thereof are omitted here.

The wiring M1 is a wiring of an arbitrary wiring layer, among a plurality of wiring layers configuring the wiring structure, while the wiring M2 is a wiring of a wiring layer directly above the wiring layer having therein the wiring M1.

The interlayer insulating film IL1 has therein at least one buried wiring M1 and actually, it has therein a plurality of buried wirings M1. The interlayer insulating film IL2 has therein at least one buried wiring M2 and actually, it has therein a plurality of buried wirings M2.

The wiring M1 is a wiring buried in a wiring trench TR1 formed in the interlayer insulating film IL1 and it is a damascene wiring (damascene buried wiring) formed by the damascene process. The wiring M2 is a wiring buried in a wiring trench TR2 formed in the interlayer insulating film IL2 and it is a damascene wiring (damascene buried wiring) formed by the damascene process. The wirings M1 and M2 are copper wirings comprised mainly of (having, as a main component thereof), copper. The wirings M1 and M2 are therefore damascene wirings (damascene copper wirings, buried copper wirings) comprised mainly of (having, as a main component thereof), copper.

The wiring M2 is a dual damascene wiring formed by the dual damascene process. The wiring M1 in FIG. 1 is a wiring of a first wiring layer (bottom wiring layer) in the wiring structure and the wiring M1 is a single damascene wiring formed by the single damascene process. The wiring M1 may be a wiring of a wiring layer above the first wiring layer in the wiring structure and the wiring M1 may be a dual damascene wiring formed by the dual damascene process.

The barrier insulating films B1 and B2 function as a barrier insulating film of the copper wiring. This means that the barrier insulating film B1 functions as a barrier insulating film of the wiring M1 and the barrier insulating film B2 functions as a barrier insulating film of the wiring M2. More specifically, the barrier insulating film B1 functions as a barrier insulating film for suppressing or preventing copper (Cu) in the wiring M1 from diffusing into an interlayer insulating film (here, the interlayer insulating film IL2) formed on the barrier insulating film B1. The barrier insulating film B2 functions as a barrier insulating film for suppressing or preventing copper (Cu) in the wiring M2 from diffusing into an interlayer insulating film (not shown in the drawing) formed on the barrier insulating film B2.

As the barrier insulating films B1 and B2, a material film excellent in barrier property against copper (Cu) (having high copper diffusion suppressing or preventing function) is therefore preferred. The barrier insulating film B1 can also function as an etching stopper in an etching step for forming a via hole (namely, “via hole VH”) in an interlayer insulating film (namely, “interlayer insulating film IL2”) on the barrier insulating film B1. Similarly, the barrier insulating film B2 can also function as an etching stopper in an etching step for forming a via hole in an interlayer insulating film (not shown in the drawing) on the barrier insulating film B2.

The barrier insulating film B1 may be a stacked film comprised of a plurality of insulating films. Similarly, the barrier insulating film B2 may be a stacked film comprised of a plurality of insulating films.

The barrier insulating film B1 can therefore be comprised of, for example, at least one layer film selected from an SiN film (silicon nitride film), an SiC film (silicon carbide film), an SiCN film (silicon carbonitride film or nitrogen-added silicon carbide film), and an SiCO film (silicon oxycarbide film or oxygen-added silicon carbide film). Similarly, the barrier insulating film B2 can also be comprised of, for example, at least one layer film selected from an SiN film (silicon nitride film), an SiC film (silicon carbide film), an SiCN film (silicon carbonitride film or nitrogen-added silicon carbide film), and an SiCO film (silicon oxycarbide film or oxygen-added silicon carbide film). As one example, a stacked film comprised of an SiCN film and an SiCO film thereon can be used as each of the barrier insulating films B1 and B2.

The interlayer insulating films IL1 and IL2 are each made of a low-dielectric-constant insulating film. The term “low-dielectric-constant insulating film” means an insulating film having a dielectric constant (specific dielectric constant) lower than that of silicon oxide (for example, TEOS (tetraethoxysilane) oxide film). The low-dielectric-constant insulating film may be called “Low-k film” or “Low-k insulating film”. The low-dielectric-constant insulating film will hereinafter be called “Low-k film” and a porous Low-k film means a porous low-dielectric-constant insulating film.

Parasitic capacitance between wirings M1 adjacent to each other can be reduced by using a low-dielectric-constant insulating film as the interlayer insulating film IL1. Similarly, parasitic capacitance between wirings M2 adjacent to each other can be reduced by using a low-dielectric-constant insulating film as the interlayer insulating film IL2. In addition, parasitic capacitance between wirings M2 and M1 can also be reduced.

By selecting, as a material of the barrier insulating films B1 and B2, a material appropriate for the function of the barrier insulating film (for example, copper diffusion preventing function) and as a material of the interlayer insulating films IL1 and IL2, a material having a low dielectric constant for reducing parasitic capacitance between wirings, a wiring structure and moreover, a semiconductor device having the wiring structure, each having improved reliability or performance, can be provided.

The dielectric constant of the interlayer insulating films IL1 and IL2 is lower than that of the barrier insulating films B1 and B2. In other words, the dielectric constant of the barrier insulating films B1 and B2 is higher than that of the interlayer insulating films IL1 and IL2.

In the present embodiment, as the low-dielectric-constant insulating film for the interlayer insulating films IL1 and IL2, a porous Low-k film (porous low-dielectric-constant insulating film) is used. The porous Low-k film has a porous structure having many (a plurality of) voids (pores) in the film and is excellent as a low-dielectric-constant insulating film because it can reduce a dielectric constant further. Since the porous Low-k film can reduce a dielectric constant compared with another low-dielectric-constant insulating film (SiOC film or the like), the porous Low-k film may be called “porous ULK (Ultra Low-k) film or porous ELK (Extreme Low-k) film. As the porous Low-k film, a porous SiOC film can be used preferably. The porous SiOC film is an SiOC film equipped with a porous structure having many (a plurality of) voids (pores) in the film.

As the interlayer insulating films IL1 and IL2, the porous Low-k film can be used as a single layer film, but it can also be used as a stacked film (stacked insulating film) including the porous Low-k film.

The porous Low-k film is porous so that it can reduce the dielectric constant, but instead, it reduces mechanical strength. By using not a single layer porous Low-k film but a stacked film of a porous Low-k film and another insulating film thereon as the interlayer insulating films IL1 and IL2, the resulting interlayer insulating films IL1 and IL2 can have improved resistance against CMP treatment at the time of damascene wiring formation and the semiconductor device thus obtained can have enhanced reliability.

In the interlayer insulating films IL1 and IL2, it is therefore preferred to use, as an insulating film formed on the porous Low-k film, an insulating film having mechanical strength higher than that of the porous Low-k film and having high resistance against CMP treatment. For example, an SiOC film (not porous SiOC film) can be used. An SiOC film is a material film (carbon-added silicon oxide film) obtained by adding carbon to silicon oxide and can be formed using CVD (chemical vapor deposition) or the like. An SiOC film is a low-dielectric-constant insulating film having a dielectric constant higher than that of a porous Low-k film but lower than that of silicon oxide. By using, as the interlayer insulating films IL1 and IL2, a stacked film of a porous Low-k film and an SiOC film thereon, the resulting interlayer insulating films IL1 and IL2 can have a reduced dielectric constant and at the same time, can have improved resistance against CMP treatment.

Alternatively, as the top layer film of the stacked film of the interlayer insulating films IL1 and IL2, a silicon oxide film can be used. For example, the interlayer insulating films IL1 and IL2 may be a stacked film of a porous Low-k film, an SiOC film thereon, and a silicon oxide film thereon. A silicon oxide film has high mechanical strength and has high resistance against CMP treatment. The interlayer insulating films IL1 and IL2 having a silicon oxide film as the top layer film of the stacked film can have further improved resistance against CMP treatment.

In FIG. 1, the interlayer insulating film IL1 is a stacked film of a porous Low-k film 1 and an SiOC film 2 on the porous Low-k film 1, while the interlayer insulating film IL2 is a stacked film of a porous Low-k film 4 and an SiOC film 5 on the porous Low-k film 4. The porous Low-k films 1 and 4 are preferably a porous SiOC film.

The wiring M1 is comprised of a barrier conductor film BR1 formed on the inner surface (the bottom surface and the side wall) of the wiring trench TR1 and a main conductor film MC1 formed on the barrier conductor film BR1 to fill the wiring trench TR1 therewith. The wiring M2 is comprised of a barrier conductor film BR2 formed on the inner surface (bottom surface and side wall) of the wiring trench TR2 and a main conductor film MC2 formed on the barrier conductor film BR2 to fill the wiring trench TR2 therewith.

The main conductor films MC1 and MC2 are each a conductive film (conductive film exhibiting metallic conduction) comprised mainly of copper (Cu) so that the wirings M1 and M2 can be regarded as a copper wiring. The main conductor films MC1 and MC2 are preferably a copper (Cu) film, a copper (Cu) alloy film, or a copper (Cu) compound film. When a copper alloy film or a copper compound film is used, however, a copper-rich (Cu-rich) copper alloy film or copper compound film is preferred. The term “copper-rich (Cu-rich)” as used herein means that a composition ratio of copper (Cu) is greater than 50 atom %.

The barrier conductor film BR1 functions as a barrier conductor film that suppresses or prevents copper (Cu) in the main conductor film MC1 from diffusing into the interlayer insulating film IL1. The barrier conductor film BR1 has also a function of improving the adhesiveness between the wiring M1 and the interlayer insulating film IL1. The barrier conductor film BR2 functions as a barrier conductor film that suppresses or prevents copper (Cu) in the main conductor film MC2 from diffusing into the interlayer insulating film IL2. The barrier conductor film BR2 has also a function of improving the adhesiveness between the wiring M2 and the interlayer insulating film IL2.

The barrier conductor film BR1 has a stacked structure in which a plurality of barrier conductor films has been stacked one after another. More specifically, the barrier conductor film BR1 is a three-layer barrier conductor film and it is a stacked film comprised of a barrier conductor film 11 as a bottom layer, a barrier conductor film 12 as an intermediate layer, and a barrier conductor film 13 as a top layer. This means that the barrier conductor film BR1 is a stacked film comprised of the barrier conductor film 11, the barrier conductor film 12 on the barrier conductor film 11, and the barrier conductor film 13 on the barrier conductor film 12.

The bottom-layer barrier conductor film 11 of the barrier conductor film BR1 is on the inner surface (the bottom surface and the side wall) of the wiring trench TR1. The barrier conductor film 11 is therefore contiguous to the interlayer insulating film IL1 (here, the porous Low-k film 1 and the SiOC film 2) on the side wall of the wiring trench TR1. The barrier conductor film 12 and the inner surface (the bottom surface and the side wall) of the wiring trench TR1 have therebetween the barrier conductor film 11. Therefore, the barrier conductor film 12 and the interlayer insulating film IL1 have therebetween the barrier conductor film 11. The barrier conductor film 13 and the barrier conductor film 11 have therebetween the barrier conductor film 12 and the main conductor film MC1 and the barrier conductor film 12 have therebetween the barrier conductor film 13.

The barrier conductor film 11 and the barrier conductor film 12 configuring the barrier conductor film BR1 are made of the same conductor material, preferably tantalum nitride (TaN). The barrier conductor film 11 and the barrier conductor film 12 are therefore each preferably made of tantalum nitride (TaN).

The barrier conductor film 11 has a density lower than that of the barrier conductor film 12. In other words, the barrier conductor film 12 has a density higher than that of the barrier conductor film 11. Therefore, the barrier conductor film 11 is preferably a low-density tantalum nitride film and the barrier conductor film 12 is preferably a high-density tantalum nitride film.

On the other hand, the barrier conductor film 13 configuring the barrier conductor film BR1 is made of a conductor material different from that of the barrier conductor films 11 and 12, preferably tantalum (Ta). The barrier conductor film 13 is preferably a tantalum (Ta) film.

The barrier conductor film BR2 has a stacked structure obtained by stacking a plurality of barrier conductor films one after another. More specifically, the barrier conductor film BR2 is a three-layer barrier conductor film and it is a stacked film of a barrier conductor film 21 as a bottom layer, a barrier conductor film 22 as an intermediate layer, and a barrier conductor film 23 as a top layer. This means that the barrier conductor film BR2 is a stacked film comprised of the barrier conductor film 21, the barrier conductor film 22 on the barrier conductor film 21, and the barrier conductor film 23 on the barrier conductor film 22.

The bottom-layer barrier conductor film 21 of the barrier conductor film BR2 is on the inner surface (the bottom surface and the side wall) of the wiring trench TR2 and on the inner surface (the bottom surface and the side wall) of the via hole VH. The barrier conductor film 21 is therefore contiguous to the interlayer insulating film IL2 (namely, the side surface of the porous Low-k film 4 and the SiOC film 5) on the side wall of the wiring trench TR2, contiguous to the interlayer insulating film IL2 (namely, the porous Low-k film 4) on the bottom surface of the wiring trench TR2, and contiguous to the interlayer insulating film IL2 (namely, the porous Low-k film 4) on the side wall of the via hole VH. The barrier conductor film 22 and the inner surface (the bottom surface and the side wall) of the wiring trench TR2 and the via hole VH have therebetween the barrier conductor film 21. The barrier conductor film 22 and the interlayer insulating film IL2 have therefore the barrier conductor film 21 therebetween. The barrier conductor film 23 and the barrier conductor film 21 have therebetween the barrier conductor film 22 and the main conductor film MC2 and the barrier conductor film 22 have therebetween the barrier conductor film 23.

The barrier conductor film 21 and the barrier conductor film 22 configuring the barrier conductor film BR2 are each made of the same conductor material, preferably tantalum nitride (TaN). The barrier conductor film 21 and the barrier conductor film 22 are therefore preferably a tantalum nitride (TaN) film.

The barrier conductor film 21 has a density lower than that of the barrier conductor film 22. In other words, the barrier conductor film 22 has a density higher than that of the barrier conductor film 21. Therefore, the barrier conductor film 21 is preferably a low-density tantalum nitride film and the barrier conductor film 22 is preferably a high-density tantalum nitride film.

On the other hand, the barrier conductor film 23 configuring the barrier conductor film BR2 is made of a conductor material different from that of the barrier conductor films 21 and 22, preferably tantalum (Ta). The barrier conductor film 23 is therefore preferably a tantalum (Ta) film.

The wiring M2 has a lower surface in the middle of the thickness of the interlayer insulating film IL2. This means that the wiring trench TR2 formed in the interlayer insulating film IL2 is filled with the wiring M2 and the wiring trench TR2 (except the via hole VH) has a bottom surface thereof in the middle of the thickness of the interlayer insulating film IL2. In other words, the via hole VH penetrates the interlayer insulating film IL2 and the barrier insulating film B1, but the wiring trench TR2 does not penetrate the interlayer insulating film IL2 and the wiring trench TR2 has a bottom surface in the middle of the thickness of the interlayer insulating film IL2. The wiring trench TR2 here has a bottom surface in the middle of the thickness of the porous Low-k film 4. Except a via portion (a portion in which the via hole VH is buried) of the wiring M2, the lower surface of the wiring M2 and the upper surface of the barrier insulating film B1 have therebetween a portion of the interlayer insulating film IL2 (namely, a portion of the porous Low-k film 4).

The wiring M2 is electrically coupled to the wiring M1 via the via portion (portion in which the via hole VH is buried) of the wiring M2. The via portion of the wiring M2 corresponds to a portion of the wiring M2 in which the via hole VH is buried. The via hole (hole portion) VH is included in the wiring trench TR2 in plan view. The via hole VH penetrates the interlayer insulating film IL2 and the barrier insulating film B1 and from the bottom surface (bottom portion) of the via hole VH, the upper surface of the wiring M1 is exposed. The wiring trench TR2 has therein the wiring M2 and the via hole VH has therein the via portion of the wiring M2. The wiring M2 is a dual damascene wiring so that the via portion (portion in which the via hole is buried) of the wiring M2 is integral with the wiring M2 (the wiring M2 buried in the wiring trench TR2). The via portion of the wiring M2 is contiguous to the upper surface of the wiring M2 and has electrical coupling to the wiring M1. As a result, the wiring M2 can be coupled to the wiring M1 via the via portion of the wiring M2.

### Method of Manufacturing a Semiconductor Device

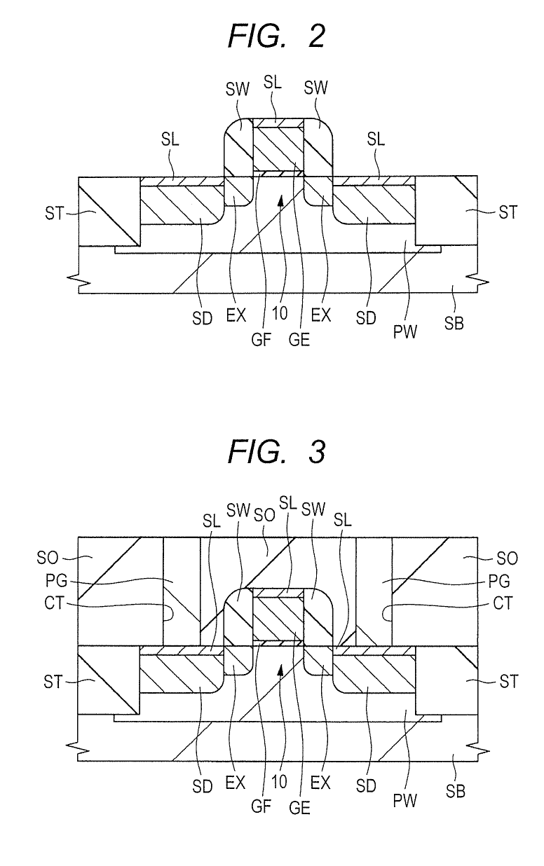

Next, manufacturing steps of the semiconductor device of the present embodiment will be described based on FIGS. 2 to 24. FIGS. 2 to 24 are fragmentary cross-sectional views of the semiconductor device of First Embodiment during manufacturing steps.

First, as shown in FIG. 2, a semiconductor substrate (semiconductor wafer) SB made of, for example, p type single crystal silicon having a specific resistance of from about 1 to 10 Ωcm is provided.

Next, an element isolation region ST is formed in the semiconductor substrate SB. The element isolation region ST can be formed by STI (shallow trench isolation).

Next, a semiconductor element such as n channel MISFET (metal insulator semiconductor field effect transistor) 10 is formed on the semiconductor substrate SB. The MISFET 10 can be formed, for example, in the following manner.

Described specifically, a p well PW is formed in the semiconductor substrate SB by ion implantation or the like. A gate electrode GE for the n channel MISFET 10 is formed on the p well PW via a gate insulating film GF. With the gate electrode GE as a mask, an n type impurity is ion-implanted into the p well PW to form, in the p well PW, an n⁻ type semiconductor region EX on both sides of the gate electrode GE. A sidewall spacer (sidewall insulating film) SW is then formed on the side wall of the gate electrode GE. With the gate electrode GE and the sidewall spacer SW as a mask, an n type impurity is ion-implanted into the p well PW to form an n⁺ type semiconductor region SD having an impurity concentration higher than that of the n⁻ type semiconductor region EX on both sides of a structure comprised of the gate electrode GE and the sidewall spacer SW. The n⁻ type semiconductor region EX and the n⁺ type semiconductor region SD configure source-drain regions of the n channel MISFET 10 having an LDD (lightly doped drain) structure. Activation annealing is then performed as heat treatment for activating the impurities so far introduced. A metal silicide layer SL may be formed on the surface layer portion of each of the gate electrode GE and the n⁺ type semiconductor region SD by salicide (salicide: self aligned silicide) technology.

The n channel MISFET 10 can thus be formed on the semiconductor substrate SB.

In the above example, an n channel MISFET formed, as a semiconductor element, on the semiconductor substrate SB is described, but a p channel MISFET may be formed on the semiconductor substrate SB by reversing the conductivity type. Both an n channel MISFET and a p channel MISFET may be formed on the semiconductor substrate SB. The semiconductor element formed on the semiconductor substrate SB is not limited to MISFET and various semiconductor elements can be formed on the semiconductor substrate SB.

Next as shown in FIG. 3, an interlayer insulating film SO is formed on the entire main surface of the semiconductor substrate SB by CVD or the like so as to cover the gate electrode GE and the sidewall spacer SW. The interlayer insulating film SO is made of, for example, a single silicon oxide film or a stacked film of a silicon nitride film and a silicon oxide film on the silicon nitride film. After formation of the interlayer insulating film SO, the upper surface of the interlayer insulating film SO is polished by CMP (chemical mechanical polishing) to planarize the upper surface of the interlayer insulating film SO.

Next, a photoresist pattern (not shown) is formed on the interlayer insulating film SO by photolithography and with this photoresist pattern as an etching mask, the interlayer insulating film SO is etched to form a contact hole CT in the interlayer insulating film SO.

Next, a conductive plug PG is formed in the contact hole CT. The plug PG is formed in the following manner. First, a conductive barrier film (for example, a titanium film or a titanium nitride film, or a stacked film of them) is formed on the interlayer insulating film SO including the inner surface (the bottom surface and the side wall) of the contact hole CT by sputtering or the like. A main conductor film made of a tungsten (W) film or the like is then formed on the conductive barrier film by CVD so as to fill the contact hole CT therewith. An unnecessary portion of the main conductor film and the conductive barrier film outside the contact hole CT is removed by CMP or the like. This makes it possible to form a plug PG made of the main conductor film and the conductive barrier film that have been buried and remained in the contact hole CT. To simplify the drawing, FIG. 3 shows, as one body, the barrier conductor film and the main conductor film configuring the plug PG.

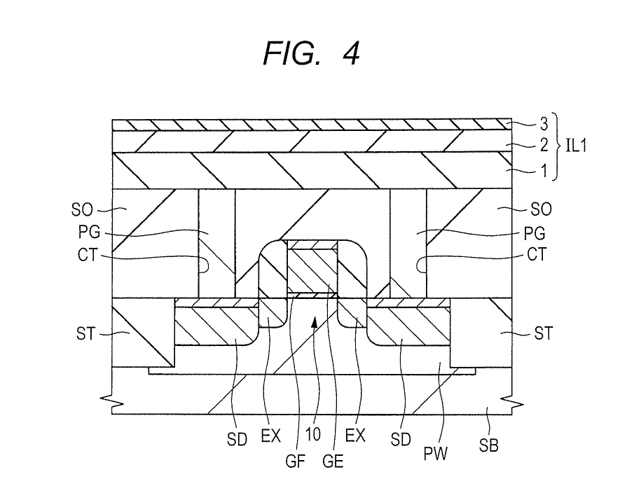

Next, as shown in FIG. 4, an interlayer insulating film IL1 is formed on the interlayer insulating film SO having therein the plug PG. The interlayer insulating film IL1 is a single-layer porous Low-k film or a stacked film including a porous Low-k film. The interlayer insulating film IL1 here is made of stacked film of a porous Low-k film 1, an SiOC film 2 on the porous Low-k film 1, and a silicon oxide film 3 (for example, TEOS oxide film) on the SiOC film 2.

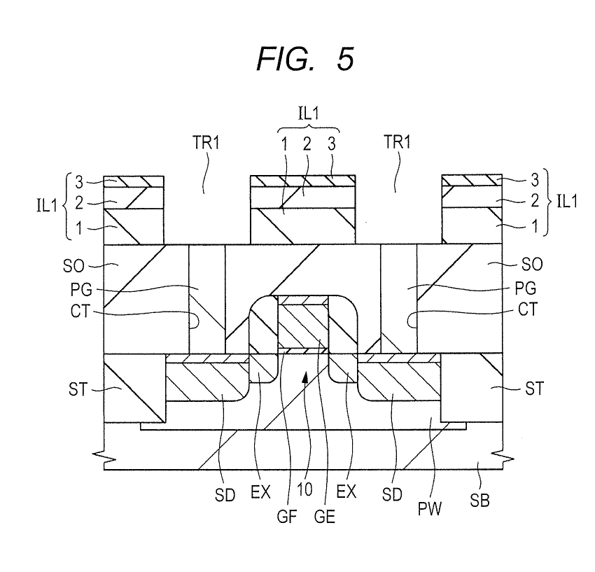

Next, a photoresist pattern (not shown) is formed on the interlayer insulating film IL1 by photolithography. With the photoresist pattern as an etching mask, the interlayer insulating film IL1 is etched to form a wiring trench (trench portion, opening portion) TR1 in the interlayer insulating film IL1 as shown in FIG. 5. The photoresist pattern is then removed. FIG. 5 shows the stage after removal.

From the side wall of the wiring trench TR1, the side surface of the interlayer insulating film IL1 (namely, the side surfaces of the porous Low-k film 1, the SiOC film 2, and the silicon oxide film 3) is exposed, while from the bottom surface of the wiring trench TR1, the upper surface of the interlayer insulating film SO is exposed.

Next, a wiring M1 is formed using the damascene process (namely, single damascene process). More specifically, the wiring M1 can be formed as described below.

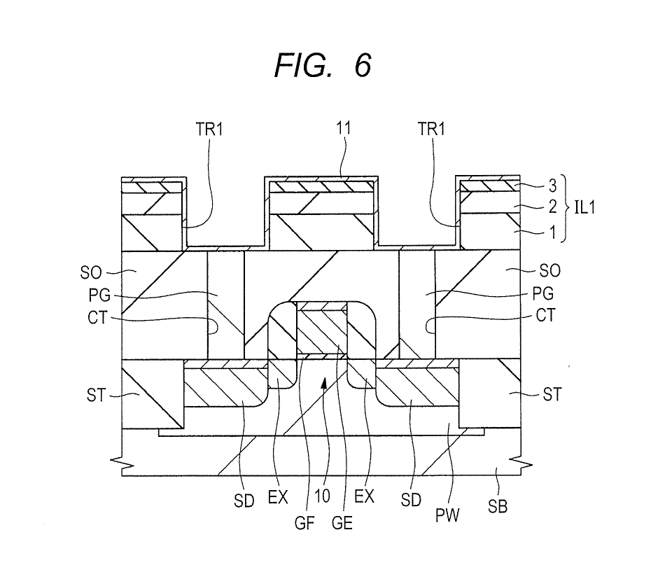

First, as shown in FIG. 6, a barrier conductor film 11 is formed on the main surface of the semiconductor substrate SB, more specifically, on the interlayer insulating film IL1 including the inner surface (the bottom surface and the side wall) of the wiring trench TR1. The barrier conductor film 11 is made of preferably a tantalum nitride (TaN) film and can be formed preferably by sputtering or ALD (atomic layer deposition). It is to be noted that sputtering can be regarded as PVD (physical vapor deposition).

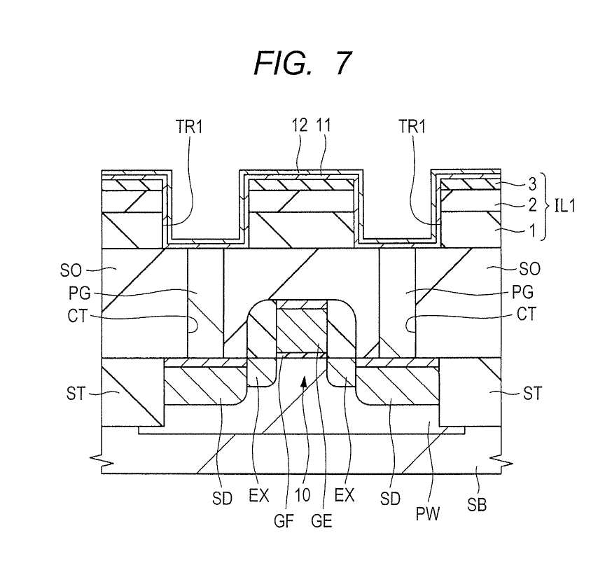

Next, as shown in FIG. 7, a barrier conductor film 12 is formed on the barrier conductor film 11. The barrier conductor film 12 is made of a conductive material same as that of the barrier conductor film 11 and it is made of a tantalum nitride (TaN) film. The barrier conductor film 12 can be formed preferably by sputtering. The barrier conductor film 11 and the barrier conductor film 12 are made of a conductive material of the same kind (namely, tantalum nitride) but the barrier conductor film 12 has a density higher than that of the barrier conductor film 11.

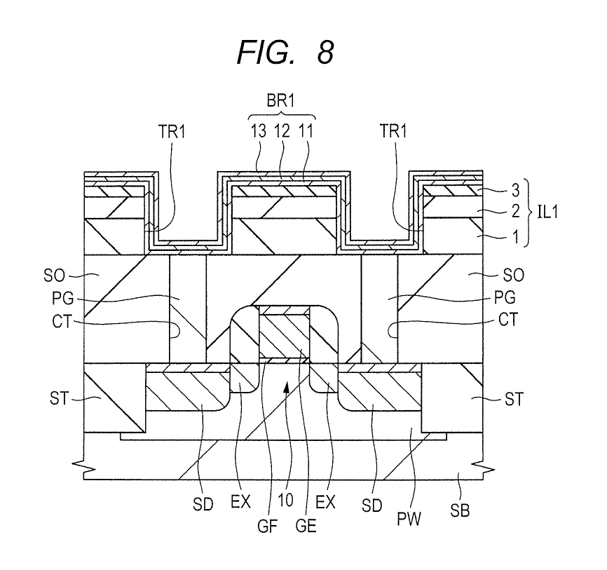

Next, as shown in FIG. 8, a barrier conductor film 13 is formed on the barrier conductor film 12. The barrier conductor film 13 is made of a conductive material different from that of the barrier conductor films 11 and 12 and it is made of a tantalum (Ta) film. The barrier conductor film 13 can be formed preferably by sputtering.

As a result, the barrier conductor film BR1 which is a stacked film of the barrier conductor film 11, the barrier conductor film 12 on the barrier conductor film 11, and the barrier conductor film 13 on the barrier conductor film 12 lies on the interlayer insulating film IL1 including the inner surface (the bottom surface and the side wall) of the wiring trench TR1. At this stage, the wiring trench TR1 remains unfilled.

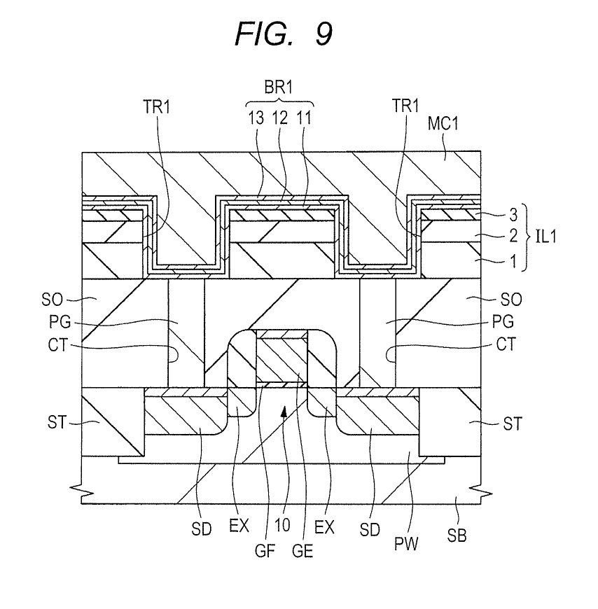

Next, as shown in FIG. 9, a main conductor film MC1 comprised mainly of copper is formed on the barrier conductor film BR1, in other words, on the barrier conductor film 13 which is the top layer of the barrier conductor film BR1, so as to fill the wiring trench TR1.

The main conductor film MC1 is comprised of a relatively thin copper seed layer formed on the barrier conductor film BR1 (therefore, on the barrier conductor film 13) by CVD, sputtering, or the like and a relatively thick copper plating film (thicker than the seed layer) formed on this copper seed layer by electroplating or the like. The wiring trench TR1 can be filled with a copper plating film. The formation thickness of the main conductor film MC1 is thicker than that of the barrier conductor film BR1.

Next, as shown in FIG. 10, a wiring M1 is formed by removing an unnecessary portion of the main conductor film MC1 and the barrier conductor film BR1 (11, 12, and 13) outside the wiring trench TR1 by polishing treatment using CMP, while leaving the other portion of the main conductor film MC1 and the barrier conductor film BR1 (11, 12, and 13) in the wiring trench TR1. The polishing treatment performed at this time will hereinafter be called “polishing treatment of FIG. 10”. The wiring M1 is comprised of the main conductor film MC1 and the barrier conductor film BR1 (11, 12, and 13) buried in the wiring trench TR1. By the polishing treatment of FIG. 10, the upper surface of the interlayer insulating film IL1 and the upper surface of the wiring M1 are exposed. As a result, the exposed upper surface of the interlayer insulating film IL1 and the exposed upper surface of the wiring M1 form a substantially flat plane.

The silicon oxide film 3 can function so as to protect the structure below the silicon oxide film 3 from the polishing pressure or scratch damage by the polishing treatment of FIG. 10. The silicon oxide film 3 can be removed by the polishing treatment of FIG. 10. By the polishing treatment of FIG. 10, the upper surface of the SiOC film 2 is exposed and the upper surface of the SiOC film 2 and the upper surface of the wiring M1 form a substantially flat plane.

FIG. 10 shows the upper surface of the SiOC film 2 exposed after removal of the silicon oxide film 3 by the polishing treatment of FIG. 10. In this case, after the polishing treatment of FIG. 10, the interlayer insulating film IL1 is a stacked film of the porous Low-k film 1 and the SiOC film 2 on the porous Low-k film 1. In another aspect, the silicon oxide film 3 may remain in layer form after the polishing treatment of FIG. 10. In this case, even after the polishing treatment of FIG. 10, the interlayer insulating film IL1 is a stacked film of the porous Low-k film 1, the SiOC film 2 on the porous Low-k film 1, and the silicon oxide film 3 on the SiOC film 2.

The wiring M1 can be formed as described above.

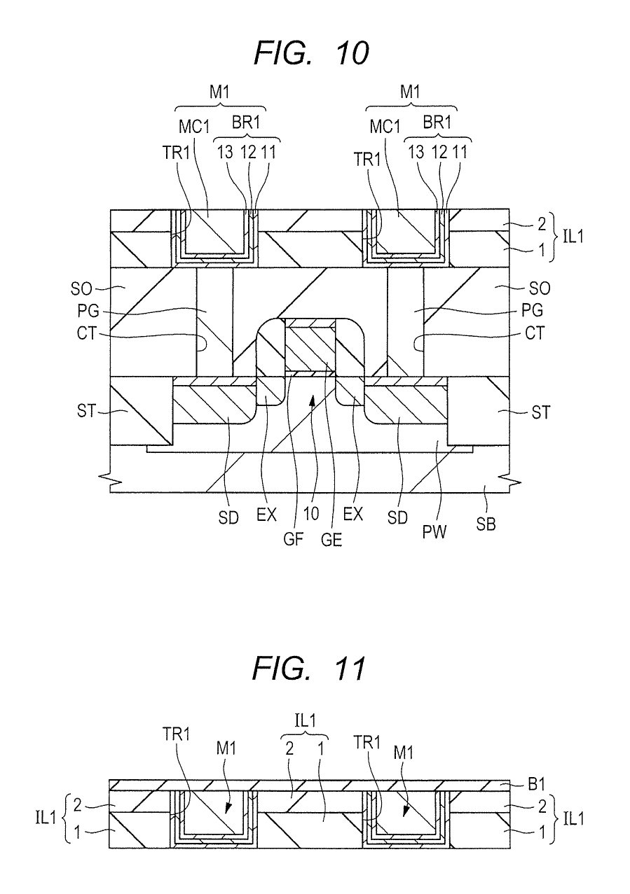

In FIGS. 11 to 24, the structure below the interlayer insulating film IL1 is omitted to simplify the drawings.

Next, the surface of the interlayer insulating film IL1 having the wiring M1 therein is subjected to ammonia plasma treatment or the like to clean the upper surface of the wiring M1 and the upper surface of the interlayer insulating film IL1.

Next, as shown in FIG. 11, a barrier insulating film B1 is formed on the interlayer insulating film IL1 having therein the wiring M1 so as to cover the wiring M1.

The barrier insulating film B1 can be formed, for example, from at least one layer selected from an SiN film, an SiC film, an SiCN film, and an SiCO film. As one example, a stacked film of an SiCN film and an SiCO film thereon can be used as the barrier insulating film B1. The barrier insulating film B1 can be formed using CVD or the like.

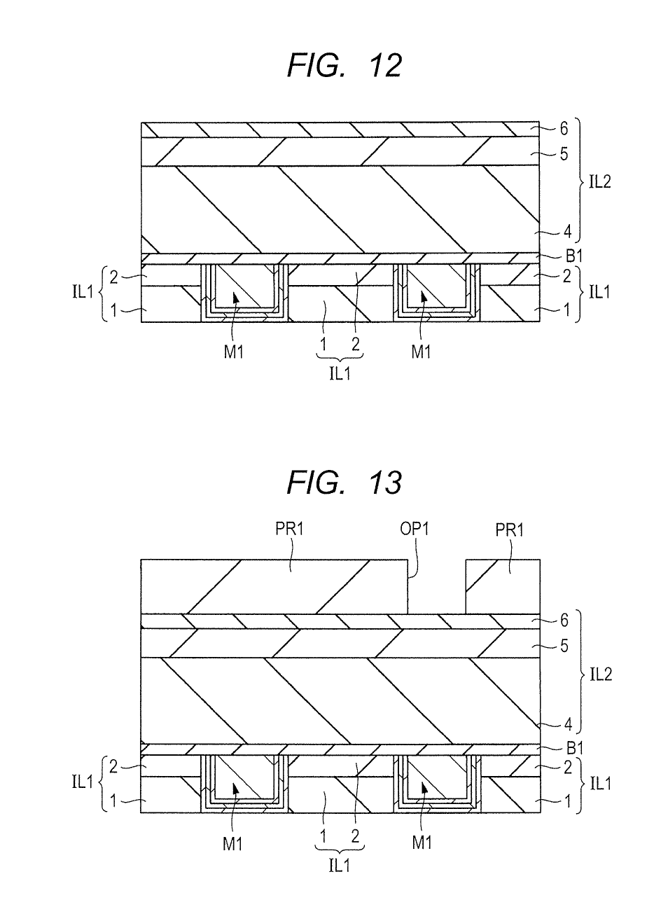

Next, as shown in FIG. 12, an interlayer insulating film IL2 is formed on the barrier insulating film B1. The interlayer insulating film IL2 is comprised of a single-layer porous Low-k film or a stacked film including a porous Low-k film. Here, the interlayer insulating film IL2 is a stacked film comprised of a porous Low-k film 4, an SiOC film 5 on the porous Low-k film 4, and a silicon oxide film 6 (for example, TEOS oxide film) on the SiOC film 5.

Next, a via hole (hole portion) VH is formed in the interlayer insulating film IL2. The via hole VH can be formed, for example, as follows.

First, as shown in FIG. 13, a photoresist pattern (resist pattern, mask layer) PR1 is formed on the interlayer insulating film IL2 by photolithography. The photoresist pattern PR1 has an opening portion OP1 from which a via hole VH formation region is exposed.

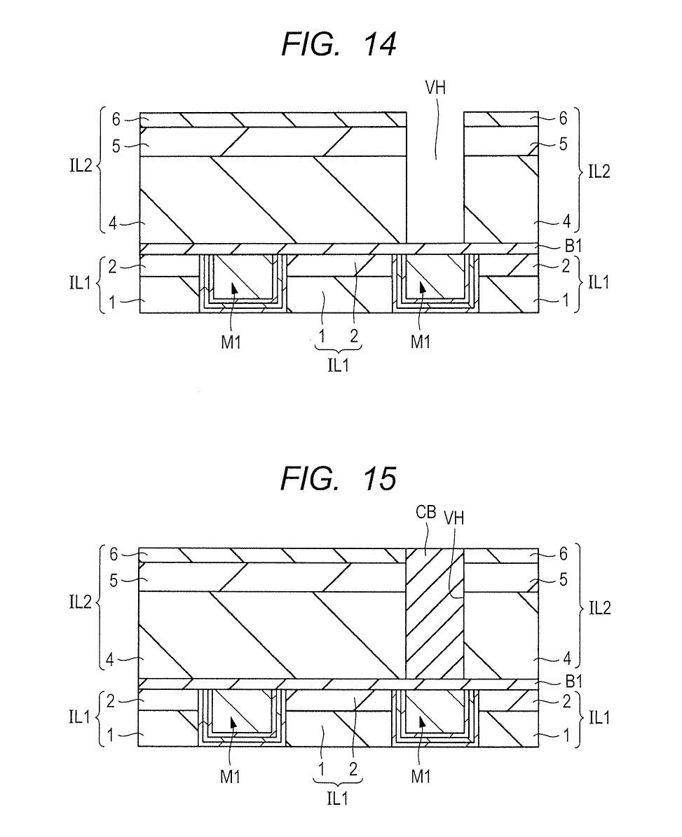

With the photoresist pattern PR1 as an etching mask, the interlayer insulating film IL2 is then etched to form a via hole VH in the interlayer insulating film IL2 as shown in FIG. 14. At this time, a portion of the interlayer insulating film IL2 exposed from the opening portion OP1 of the photoresist pattern PR1 is etched to form the via hole VH. During etching the interlayer insulating film IL2 to form the via hole VH, the barrier insulating film B1 can be functioned as an etching stopper film. The photoresist pattern PR1 is then removed, which is shown in FIG. 14.

In such a manner, the via hole VH can be formed in the interlayer insulating film IL2. The via hole VH at this stage penetrates the interlayer insulating film IL2 and expose the barrier insulating film B1 from its bottom surface (bottom portion).

Next, a wiring trench (trench portion) TR2 is formed in the interlayer insulating film IL2. The wiring trench TR2 can be formed, for example, in the following manner.

As shown in FIG. 15, first, the via hole VH is filled with an insulating film CB (via filler). This structure can be obtained, for example, by forming the insulating film CB on the interlayer insulating film IL2 so as to fill the via hole VH with it and removing the insulating film CB outside the via hole VH by etch back or the like while leaving the insulating film CB in the via hole VH. The insulating film CB is preferably made of a material easily and selectively removable later. It is made of, for example, a resist film (resist material film) or an organic film (organic insulating film).

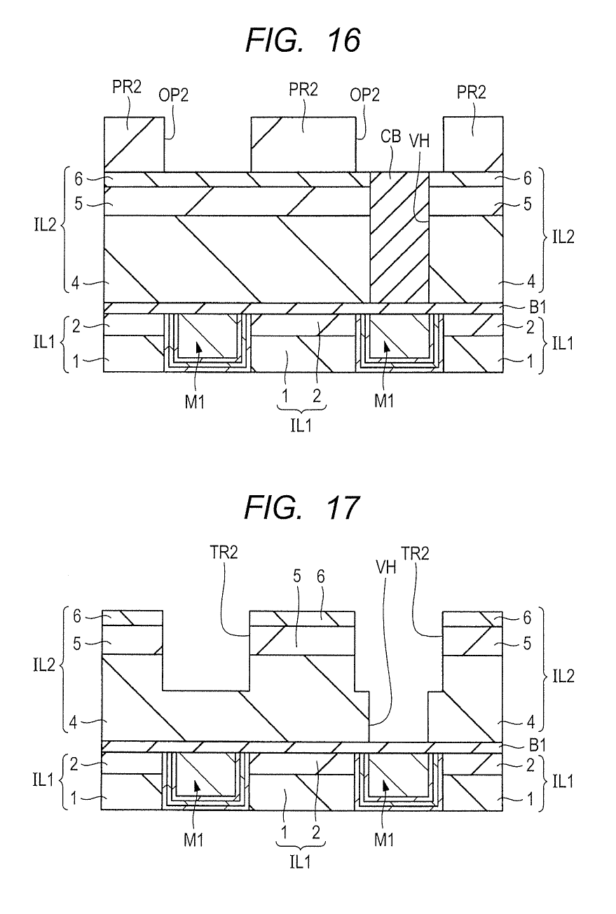

As shown in FIG. 16, a photoresist pattern (resist pattern, mask) PR2 is then formed on the interlayer insulating film IL2 by photolithography. The photoresist pattern PR2 has an opening portion OP2 from which a formation region of the wiring trench TR2 is exposed.

Then, with the photoresist pattern PR2 as an etching mask, the silicon oxide film 6 is etched to form a trench TR2 in the silicon oxide film. At this time, a portion of the silicon oxide film 6 exposed from the opening portion OP2 of the photoresist pattern PR2 is etched to form the wiring trench TR2. At this time, the SiOC film 5 can be functioned as an etching stopper film. At this stage, the wiring trench TR2 has a shallow depth and from the bottom surface of the wiring trench TR2, the SiOC film 5 is exposed.

The photoresist pattern PR2 and the insulating film CB in the via hole VH are then removed. When the insulating film CB is made of a material (for example, a resist material) removable by ashing, the insulating film CB in the via hole VH can be removed together with the photoresist pattern PR2 by ashing.

With the silicon oxide film 6 as an etching mask (hard mask), the SiOC film 5 and the porous Low-k film 4 on the bottom surface of the wiring trench TR2 are then etched. This etching lowers the position of the bottom surface of the wiring trench TR2. Etching is however terminated before the wiring trench TR2 penetrates the interlayer insulating film IL2. FIG. 17 shows this stage.

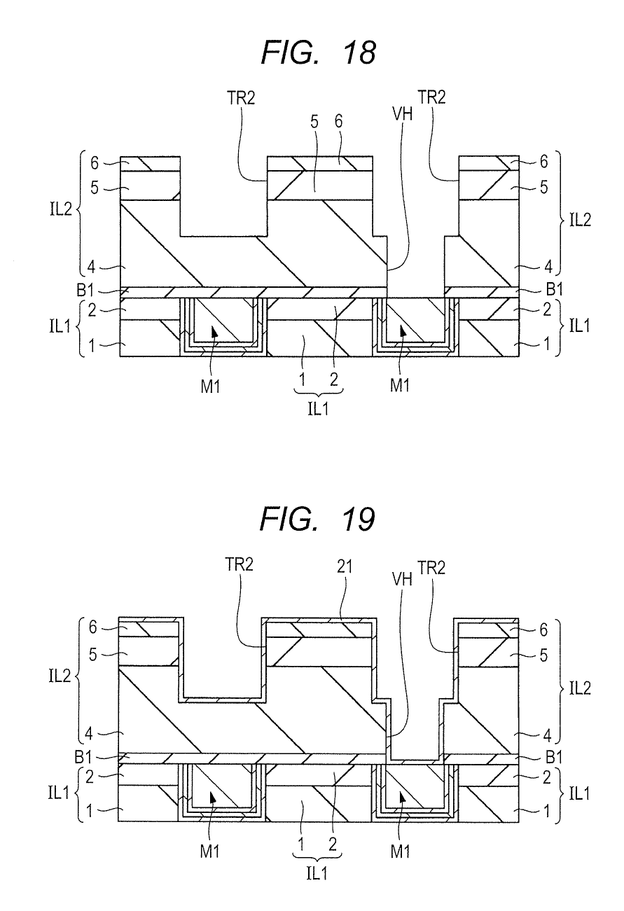

Then, as shown in FIG. 18, a portion of the barrier insulating film B1 exposed from the bottom surface of the via hole VH is removed by etching. This exposes the upper surface of the wiring M1 from the bottom surface of the via hole VH.

In such a manner, the wiring trench TR2 and the via hole VH are formed.

As shown in FIG. 18, the wiring trench TR2 does not penetrate the interlayer insulating film IL2 and the bottom surface of the wiring trench TR2 is located in the middle of the thickness of the interlayer insulating film IL2, more specifically, in the middle of the thickness of the porous Low-k film 4. The via hole VH is included in the wiring trench TR2 in plan view, penetrates the interlayer insulating film IL2 and the barrier insulating film B1, and exposes the upper surface of the wiring M1 from the bottom surface of the via hole VH.

From the side wall of the wiring trench TR2, the side surface of the interlayer insulating film IL2 (namely, the side surface of the porous Low-k film 4, the SiOC film 5, and the silicon oxide film 6) is exposed and from the bottom surface of the wiring trench TR2, the interlayer insulating film IL2 (namely, the porous Low-k film 4) is exposed. From the side wall of the via hole VH, the side surface of the interlayer insulating film IL2 (namely, the side surface of the porous Low-k film 4) is exposed and from the bottom surface of the via hole VH, the upper surface of the wiring M1 is exposed.

Next, a wiring M2 is formed by the damascene process (the dual damascene process, here). More specifically, the wiring M2 can be formed in the following manner.

First, as shown in FIG. 19, a barrier conductor film 21 is formed on the main surface of the semiconductor substrate SB, more specifically, on the interlayer insulating film IL2 including the inner surface (the bottom surface and the side wall) of the wiring trench TR2 and the via hole VH. The barrier conductor film 21 is made of a tantalum nitride (TaN) film and can be formed preferably by sputtering or ALD.

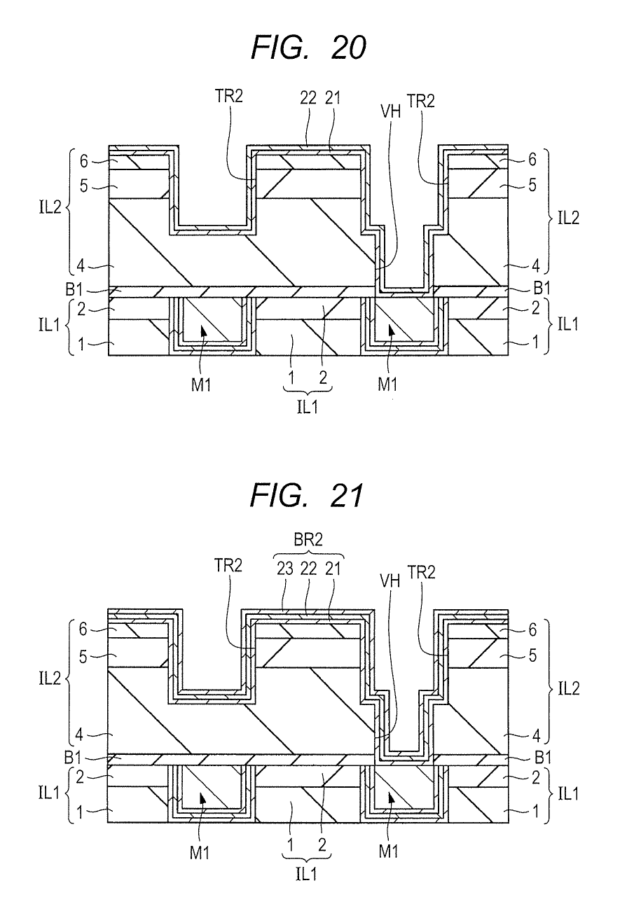

Next, as shown in FIG. 20, a barrier conductor film 22 is formed on the barrier conductor film 21. The barrier conductor film 22 is made of a conductive material same as that of the barrier conductor film 21 and here, it is made of a tantalum nitride (TaN) film. The barrier conductor film 22 can be formed preferably by sputtering. The barrier conductor film 21 and the barrier conductor film 22 are made of a conductive material of the same kind (tantalum nitride, here), but the barrier conductor film 22 has a density higher than that of the barrier conductor film 21.

Next, as shown in FIG. 21, a barrier conductor film 23 is formed on the barrier conductor film 22. The barrier conductor film 23 is made of a conductive material different from that of the barrier conductor films 21 and 22 and here, it is made of a tantalum (Ta) film. The barrier conductor film 23 can be formed preferably by sputtering.

As a result, a barrier conductor film BR2 which is a stacked film of the barrier conductor film 21, the barrier conductor film 22 on the barrier conductor film 21, and the barrier conductor film 23 on the barrier conductor film 22 lies on the interlayer insulating film IL2 including the inner surface (the bottom surface and the side wall) of the wiring trench TR2 and the via hole VH. At this stage, the wiring trench TR2 and the via hole VH have remained unfilled.

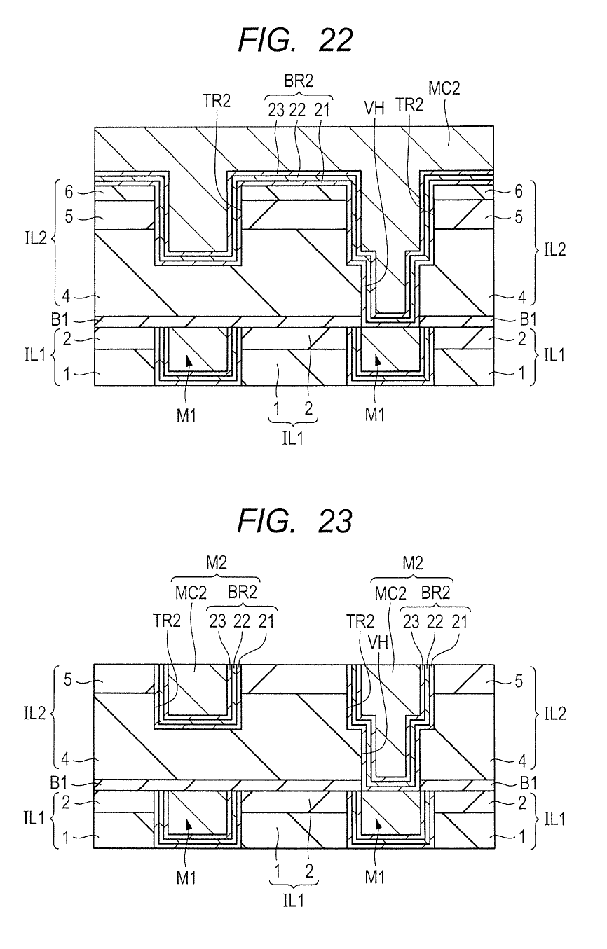

Next, as shown in FIG. 22, a main conductor film MC2 comprised mainly of copper is formed on the barrier conductor film BR2, that is, on the top-layer barrier conductor film 23 of the barrier conductor film BR2 so as to fill the wiring trench TR2 and the via hole VH with it.

The main conductor film MC2 is comprised of, for example, a relatively thin copper seed layer formed on the barrier conductor film BR2 (therefore, on the barrier conductor film 23) by CVD, sputtering, or the like and a relatively thick copper plating film formed on this copper seed layer by electroplating or the like. The wiring trench TR2 and the via hole VH can be filled with this copper plating film. The copper plating film has a thickness greater than that of the copper seed layer. The formation thickness of the main conductor film MC2 is greater than that of the barrier conductor film BR2.

Next, as shown in FIG. 23, a wiring M2 is formed by removing an unnecessary portion of the main conductor film MC2 and the barrier conductor film BR2 (21, 22, and 23) outside the wiring trench TR2 and the via hole VH by polishing treatment using CMP, while leaving the other portion of the main conductor film MC2 and the barrier conductor film BR2 (21, 22, and 23) in the wiring trench TR2 and the via hole VH. The polishing treatment performed in this step will hereinafter be called “polishing treatment of FIG. 23”. The wiring M2 is comprised of the main conductor film MC2 and the barrier conductor film BR2 (21, 22, and 23) buried in the wiring trench TR2. By the polishing treatment of FIG. 23, the upper surface of the interlayer insulating film IL2 and the upper surface of the wiring M2 are exposed and the upper surface from which the interlayer insulating film IL2 is exposed and the upper surface from which the wiring M2 is exposed form a substantially flat plane.

The main conductor film MC2 and the barrier conductor film BR2 in the via hole VH form the via portion of the wiring M2. The via portion of the wiring M2 which has filled the via hole VH is integral with the wiring M2 that has filled the wiring trench TR. The via portion of the wiring M2 can therefore be regarded as a portion of the wiring M2. The via portion of the wiring M2 is contiguous to the upper surface of the wiring M1 and has electrical coupling to the wiring M1. The wiring M2 can therefore be electrically coupled to the wiring M1 via the via portion of the wiring M2.

The silicon oxide film 6 can function so as to protect the structure below the silicon oxide film 6 from the polishing pressure or scratch damage caused by the polishing treatment in FIG. 23. The silicon oxide film 6 can be removed by the polishing treatment of FIG. 23. By the polishing treatment of FIG. 23, the upper surface of the SiOC film 5 is exposed and the upper surface of the SiOC film 5 and the upper surface of the wiring M2 form a substantially flat plane.

FIG. 23 shows the upper surface of the SiOC film 5 exposed by the polishing treatment of FIG. 23 for the removal of the silicon oxide film 6. In this case, after the polishing treatment of FIG. 23, the interlayer insulating film IL2 is a stacked film of the porous Low-k film 4 and the SiOC film 5 on the porous Low-k film 4. In another aspect, the silicon oxide film 6 may remain in layer form after the polishing treatment of FIG. 23. In this case, even after the polishing treatment of FIG. 23, the interlayer insulating film IL2 is a stacked film of the porous Low-k film 4, the SiOC film 5 on the porous Low-k film 4, and the silicon oxide film 6 on the SiOC film 5.

The wiring M2 can be formed in such a manner.

Next, the surface of the interlayer insulating film IL2 having the wiring M2 therein is subjected to ammonia plasma treatment to clean the upper surface of the wiring M2 and the upper surface of the interlayer insulating film IL2.

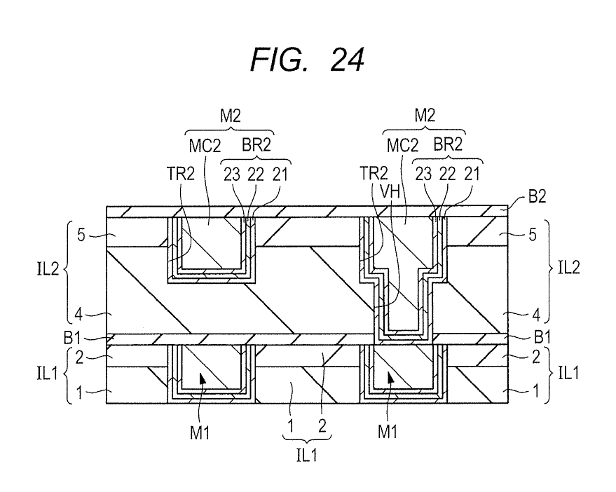

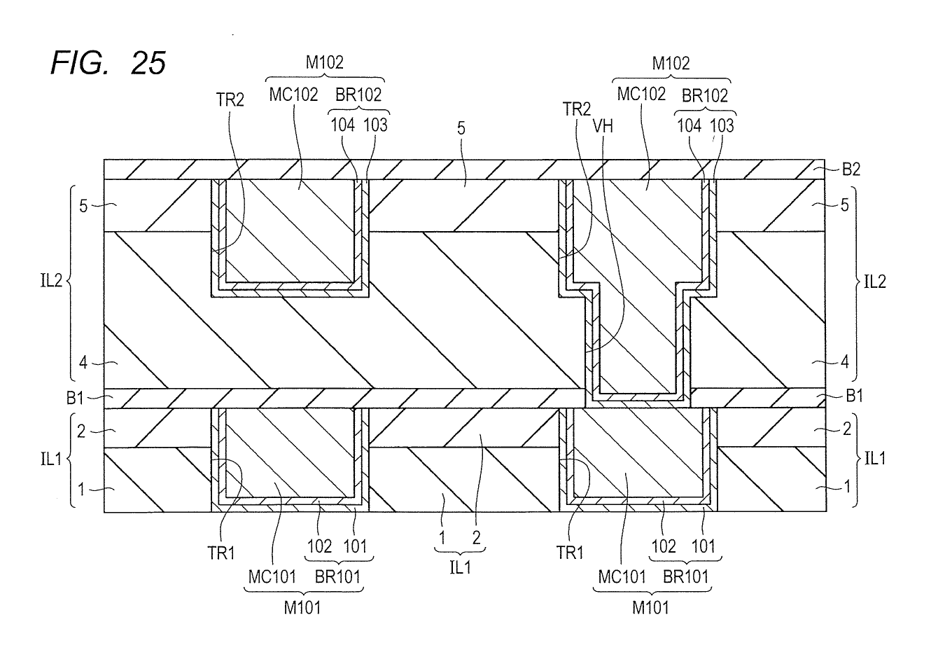

Next, as shown in FIG. 24, a barrier insulating film B2 is formed on the interlayer insulating film IL2 having therein the wiring M2 so as to cover the wiring M2.

The barrier insulating film B2 can be formed, for example, from at least one layer selected from an SiN film, an SiC film, an SiCN film, and an SiCO film. As one example, a stacked film of an SiCN film and an SiCO film thereon can be used as the barrier insulating film B2. The barrier insulating film B2 can be formed using CVD or the like.

Wiring layers above it can be formed further by repeating steps similar to those of from FIG. 12 to FIG. 24, but illustration and overlapping description are omitted. In short, a wiring is formed by forming an interlayer insulating film corresponding to the interlayer insulating film IL2 on the barrier insulating film B2, forming a wiring trench corresponding to the wiring trench TR2 and a via hole corresponding to the via hole VH in the stacked film of the barrier insulating film B2 and the interlayer insulating film, and filling the wiring trench and the via hole with a barrier conductor film corresponding to the barrier conductor film BR2 and a main conductor film corresponding to the main conductor film MC2. A barrier insulating film corresponding to the barrier insulating film B2 is then formed. The procedure described above may be repeated as needed.

### Investigation by the Present Inventors

The present inventors investigated a technology about a copper wiring (buried copper wiring) buried in an interlayer insulating film, particularly, a barrier conductor film.

FIG. 25 is a fragmentary cross-sectional view of a semiconductor device of First Investigation Example investigated by the present inventors and it corresponds to FIG. 1.

A difference of the semiconductor device of First Investigation Example shown in FIG. 25 from the semiconductor device of First Embodiment shown in FIG. 1 is the configuration of a buried copper wiring, particularly, the configuration of a barrier conductor film. The semiconductor device of First Investigation Example shown in FIG. 25 and the semiconductor device of First Embodiment shown in FIG. 1 are common to each other in the barrier insulating films (B1 and B2) and the interlayer insulating films (IL1 and IL2).

A buried copper wiring is comprised of a barrier conductor film and a main conductor film comprised mainly of copper. In First Embodiment shown in FIG. 1, the wiring M1 which is buried copper wiring is comprised of the barrier conductor film BR1 and the main conductor film MC1 comprised mainly of copper, and the wiring M2 which is a buried copper wiring is comprised of the barrier conductor film BR2 and the main conductor film MC2 comprised mainly of copper. In First Investigation Example shown in FIG. 25, on the other hand, a wiring M101 which is a buried copper wiring is comprised of a barrier conductor film BR101 and a main conductor film MC101 comprised mainly of copper, and a wiring M102 which is a buried copper wiring is comprised of a barrier conductor film BR102 and a main conductor film MC102 comprised mainly of copper.

The wiring M101 corresponds to the wiring M1 of First Embodiment and it is in the interlayer insulating film ILL while the wiring M102 corresponds to the wiring M2 of First Embodiment and it is in the interlayer insulating film IL2.

The barrier conductor films (BR1, BR2, BR101, and BR102) configuring the buried copper wiring have a function of suppressing or preventing copper (Cu) of the copper main conductor films (MC1, MC2, MC101, and MC102) from diffusing into the interlayer insulating films (IL1 and IL2). The barrier conductor films (BR1, BR2, BR101, and BR102) configuring the buried copper wiring also have a function of improving the adhesiveness between the buried copper wiring and the interlayer insulating films (L1 and IL2).

As the barrier conductor film configuring the buried copper wiring, a material film excellent in barrier property against copper (Cu), that is, a material film having high function of suppressing or preventing diffusion of copper (Cu) is preferred. In addition, as the barrier conductor film configuring the buried copper wiring, a material film capable of improving the adhesiveness between the buried copper wiring and the interlayer insulating film is preferred. Judging from above, a tantalum film or a tantalum nitride film is preferred as the barrier conductor film configuring the buried copper wiring.

In First Investigation Example of FIG. 25, the barrier conductor film BR101 of the wiring M101 is a stacked film of a tantalum nitride (TaN) film 101 and a tantalum (Ta) film 102 on the tantalum nitride film 101, and the barrier conductor film BR102 of the wiring M102 is comprised of a tantalum nitride (TaN) film 103 and a tantalum (Ta) film 104 on the tantalum nitride film 103.

The tantalum nitride film and the tantalum film are each excellent in barrier property against copper (Cu). The tantalum nitride film is excellent in adhesiveness with an interlayer insulating film, while the tantalum film is excellent in adhesiveness with the copper main conductor film. By using, as the barrier conductor film, a stacked film of a tantalum nitride film and a tantalum film on the tantalum nitride film, diffusion of copper (Cu) in the buried copper wiring into an interlayer insulating film can be suppressed or prevented and in addition, adhesiveness between the buried copper wiring and the interlayer insulating film can be improved.

The tantalum nitride films 101 and 103 used in First Investigation Example of FIG. 25 are each made of a high-density tantalum nitride film, that is, a dense tantalum nitride film. In order to obtain tantalum nitride films 101 and 103 having enhanced barrier property against copper (Cu), using a high-density tantalum nitride film, that is, a dense tantalum nitride film is advantageous.

According to the investigation, the present inventors have elucidated that the following problem occurs in First Investigation Example of FIG. 25.

Described specifically, when the tantalum nitride films 101 and 103 are a high density tantalum nitride film, in other words, a dense tantalum nitride film, the interlayer insulating films IL1 and IL2 are likely to be damaged during formation of the tantalum nitride films 101 and 103. In particular, when the tantalum nitride films 101 and 103 are formed by sputtering, forming the tantalum nitride films 101 and 103 having an increased density is likely to damage the interlayer insulating film due to an increase in impact caused by collision of sputter particles flown from a target at the time of film formation. As a result, the interlayer insulating film is likely to be damaged.

The damage to the interlayer insulating film during formation of the tantalum nitride films 101 and 103 becomes a problem when the interlayer insulating film includes a porous Low-k film. The porous Low-k film is porous and therefore contributes to reduction in dielectric constant, but it has weak mechanical strength and has low resistance against damage caused during formation of the tantalum nitride films 101 and 103. In other words, the porous Low-k film is susceptible to damage due to physical impact of sputter particles flown from a target during formation of the tantalum nitride films 101 and 103 by sputtering and is strongly influenced by the damage. When the porous Low-K film included in the interlayer insulating films IL1 and Il2 is damaged, the semiconductor device thus obtained may have deteriorated reliability. For example, when the porous Low-k film included in the interlayer insulating films IL1 and IL2 is damaged, the porous Low-k film becomes hygroscopic. Moisture absorption of the porous Low-k film causes oxidation of the barrier conductor films BR101 and BR102, which may result in deterioration in adhesiveness between the wirings M101 and M102 and the interlayer insulating films IL1 and IL2 or deterioration in reliability (reliability in EM life, SM life, TDDB life, or the like). This reliability of the wiring is evaluated from the standpoint of EM (electromigration) life, SM (stress migration) life, TDDB (time dependent dielectric breakdown) life, or the like. In addition, the porous Low-k film which has absorbed moisture may increase the dielectric constant of the interlayer insulating films IL1 and IL2. Due to these problems, the semiconductor device thus obtained may have deteriorated reliability.

The interlayer insulating film IL1 or IL2 not including a porous Low-k film may be another possible measure. The porous Low-k film is however excellent as a low-dielectric-constant insulating film because it reduces the dielectric constant more easily than a non-porous Low-k film. The interlayer insulting film IL1 or IL2 including the porous Low-k film can enhance the effect of reducing a parasitic capacitance between wirings. The present inventors therefore have studied a structure in which a porous Low-k film is resistant to damage during formation of a barrier conductor film of a buried copper wiring, even when the interlayer insulating film includes the porous Low-k film.

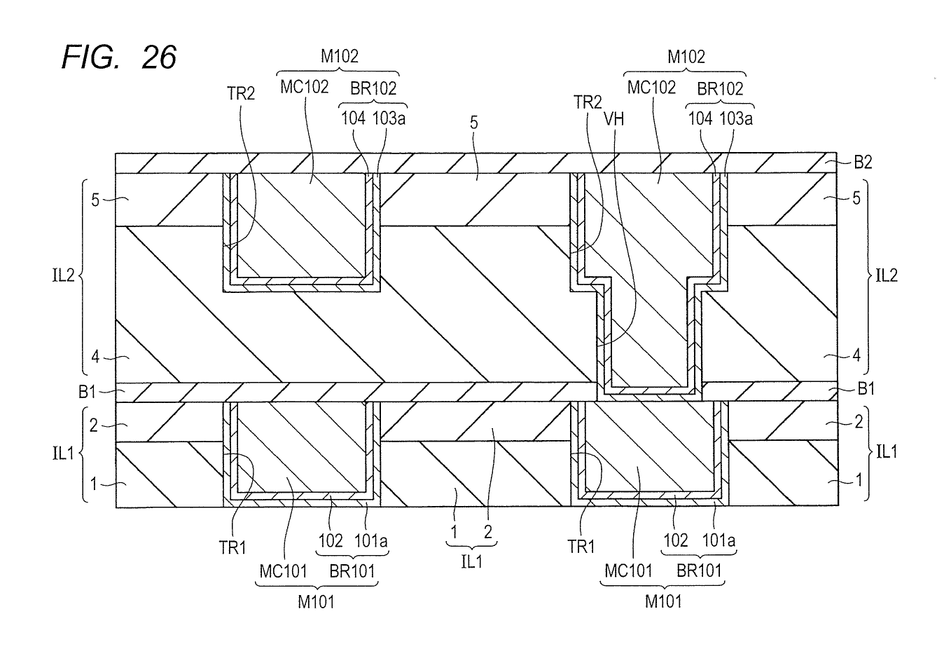

FIG. 26 is a fragmentary cross-sectional view of a semiconductor device of Second Investigation Example investigated by the present inventors. It corresponds to FIG. 1 or FIG. 25.

A difference of the semiconductor device of Second Investigation Example shown in FIG. 26 from the semiconductor device of First Investigation Example shown in FIG. 25 is that a low-density tantalum nitride film 101a is used instead of the high-density tantalum nitride film 101 and a low-density tantalum nitride 103a is used instead of the high-density tantalum nitride film 103. In Second Investigation Example shown in FIG. 26, the barrier conductor film BR101 of the wiring M101 is a stacked film of the low-density tantalum nitride film 101a and the tantalum film 102 on the tantalum nitride film 101a; and the barrier conductor film BR102 of the wiring M102 is a stacked film of the low-density tantalum nitride film 103a and the tantalum film 104 on the tantalum nitride film 103a. The tantalum nitride films 101a and 103a of Second Investigation Example each have a density lower than that of the tantalum nitride films 101 and 103 of First Investigation Example.

In Second Investigation Example of FIG. 26, the tantalum nitride films 101a and 103a are a low-density tantalum nitride film so that during formation of the tantalum nitride films 101a and 103a, the interlayer insulating films IL1 and IL2 are not easily damaged. Described specifically, when at the time of forming the tantalum nitride films 101a and 103a by sputtering, the tantalum nitride films 101a and 103a having low density are formed, impact of sputter particles flown from a target during film formation on the interlayer insulating film can be reduced and the interlayer insulating film is therefore not easily damaged. When the high-density tantalum nitride films 101 and 103 are formed using sputtering as in First Investigation Example, the porous Low-k film included in the interlayer insulating films IL1 and IL2 are inevitably damaged, but when the low-density tantalum nitride films 101a and 103a are formed using sputtering as in Second Investigation Example, the porous Low-k film included in the interlayer insulating films IL1 and IL2 are not easily damaged. In Second Investigation Example of FIG. 26 compared with First Investigation Example of FIG. 25, deterioration in reliability can be suppressed, which may occur due to the damage of the porous Low-k film included in the interlayer insulating films IL1 and IL2 at the time of formation of the barrier conductor film of the buried copper wiring.

The following problem however occurs in Second Investigation Example of FIG. 26.

Low density of the tantalum nitride film 101a leads to low adhesiveness (adhesive strength) between the tantalum nitride film 101a and the tantalum film 102 formed thereon and as a result, the tantalum nitride film 101a is likely to separate from the tantalum film 102. This occurs because the low density tantalum nitride film 101a has low surface flatness so that adhesiveness between the tantalum nitride film 101a and the tantalum film 102 formed thereon cannot easily be secured.

This means that in First Investigation Example of FIG. 25, the tantalum nitride film 101 has high density and high surface flatness and therefore, adhesiveness between the tantalum nitride film 101 and the tantalum film 102 formed thereon can easily be secured. In Second Investigation Example of FIG. 26, on the other hand, the tantalum nitride film 101a has low density and therefore has low surface flatness so that adhesiveness between the tantalum nitride film 101a and the tantalum film 102 formed thereon inevitably decreases. Similarly, in Second Investigation Example of FIG. 26, the tantalum nitride film 103a has low density and therefore has low surface flatness so that adhesiveness between the tantalum nitride film 103a and the tantalum film 104 formed thereon inevitably decreases.

A decrease in adhesiveness between the tantalum nitride film 101a and the tantalum film 102 or a decrease in adhesiveness between the tantalum nitride film 103a and the tantalum film 104 leads to deterioration in the reliability of the wirings M101 and M102. As a result, the semiconductor device thus obtained has deteriorated reliability.

The semiconductor device obtained in First Investigation Example of FIG. 25 and that obtained in Second Investigation Example of FIG. 26 each inevitably have deteriorated reliability due to the barrier conductor film of the buried copper wiring.

### Major Characteristics and Advantages

One of the major characteristics of First Embodiment is that the barrier conductor films (BR1 and BR2) of buried copper wirings (M1 and M2) have the first barrier conductor films (11 and 21), the second barrier conductor films (12 and 22) formed on the first barrier conductor films (11 and 21), and the third barrier conductor films (13 and 23) formed on the second barrier conductor films (12 and 22), respectively. The first barrier conductor films (11 and 21) lie on the bottom surface and side wall of the wiring trenches (TR1 and TR2) of the interlayer insulating films (IL1 and IL2). The main conductor films (MC1 and MC2) comprised mainly of copper lie on the third barrier conductor films (13 and 23). The first barrier conductor films (11 and 21) and the second barrier conductor films (12 and 22) are made of the same conductor material and the third barrier conductor films (13 and 23) are made of a conductor material different from that of the first barrier conductor films (11 and 21) or the second barrier conductor films (12 and 22); and the first barrier conductor films (11 and 21) have a density lower than that of the second barrier conductor films (12 and 22).

With regard to the wiring M1, the barrier conductor film 11, the barrier conductor film 12, and the barrier conductor film 13 correspond to the first barrier conductor film, the second barrier conductor film, and the third barrier conductor film, respectively. With regard to the second wiring M2, the barrier conductor film 21, the barrier conductor film 22, and the barrier conductor film 23 correspond to the first barrier conductor film, the second barrier conductor film, and the third barrier conductor film, respectively.

In First Embodiment, the first barrier conductor films (11 and 21) formed on the bottom surface and side wall of the wiring trenches (TR1 and TR2) in the interlayer insulating films (IL1 and IL2) are formed as a low density film. If the first barrier conductor films (11 and 21) are formed as a high density film, in other words, the first barrier conductor films (11 and 21) are formed as a dense film, the porous Low-k films (1 and 4) included in the interlayer insulating films (IL1 and IL2) are inevitably damaged during formation of the first barrier conductor films (11 and 21) as described above referring to First Investigation Example of FIG. 25. In the present embodiment, however, the first barrier conductor films (11 and 21) are formed as a low density film so that the porous Low-k films (1 and 4) included in the interlayer insulating films (IL1 and IL3) can be prevented from being damaged during formation of the first barrier conductor films (11 and 21). In short, in First Embodiment, by setting the density of the first barrier conductor films (11 and 21) to a low density, the first barrier conductor films (11 and 21) can be formed while suppressing or preventing the porous Low-k films (1 and 4) exposed from the wiring trenches (TR1 and TR2) from being damaged. As a result, the semiconductor device thus obtained can have improved reliability.

For example, when the porous Low-k films (1 and 4) are damaged, the porous Low-k films are likely to absorb moisture. The porous Low-k films which have absorbed moisture cause oxidation of the barrier conductor films and thereby deteriorate the adhesiveness between the wirings (M1 and M2) and the interlayer insulating films (IL1 and IL2) or deteriorate the reliability (reliability in EM life, SM life, TDDB life, or the like) of the wirings (M1 and M2). In First Embodiment, on the other hand, the porous Low-k films (1 and 4) included in the interlayer insulating films (IL1 and IL2) can be suppressed or prevented from being damaged so that inconveniences which will otherwise occur when the porous Low-k films (1,4) are damaged can be reduced or eliminated. As a result, the semiconductor device can have improved reliability.

Further, in the present embodiment, the first barrier conductor films (11 and 21) have thereon the second barrier conductor films (12 and 22) made of a conductor material same as that of the first barrier conductor films (11 and 21) and the density of the second barrier conductor films (12 and 22) is set to a density higher than that of the first barrier conductor films (11 and 21).

As in Second Investigation Example of FIG. 26, when barrier conductor films (tantalum films 102 and 104) made of a material different from that of the low density barrier conductor films (101a and 103a) are formed on the low-density barrier conductor films (corresponding to the tantalum nitride films 101a and 103a), these barrier conductor films are likely to separate from each other due to reduced adhesiveness (adhesive strength) between them.

When different from First Embodiment, the low-density first barrier conductor films (11 and 21) have thereon a conductor film made of a material different from the first barrier conductor films (11 and 21), the conductor film is likely to separate from the low-density first barrier conductor films (11 and 21) due to reduced adhesiveness (adhesive strength) therebetween.

In First Embodiment, however, since the low-density first barrier conductor films (11 and 21) have thereon the second barrier conductor films (12 and 22) made of a material same as that of the first barrier conductor films (11 and 21), adhesiveness (adhesive strength) between the second barrier conductor films (12 and 22) and the first barrier conductor films (11 and 21) can be secured even if the density of the first barrier conductor films (11 and 21) is small. This is because when a two-layer film is formed, adhesiveness (adhesive strength) between two films configuring the two-layer film can be secured more easily and separation is more unlikely to occur when the two films are made of the same material than when the two films are made of respectively different materials. When the two films are made of respectively different materials, separation due to distortion is likely to result from a difference in crystal structure or lattice constant between the two films, while when the two films are made of the same material, separation due to distortion are unlikely to occur between these two films.

In the present embodiment, since the first barrier conductor films (11 and 21) have thereon the second barrier conductor films (12 and 22) made of a material same as that of the first barrier conductor films (11 and 21), adhesiveness between the second barrier conductor films (12 and 22) and the first barrier conductor films (11 and 21) can be secured even if the first barrier conductor films (11 and 21) have a low density and therefore has poor surface flatness. Therefore, separation between the second barrier conductor films (12 and 22) and the first barrier conductor films (11 and 21) can be suppressed or prevented by the enhanced adhesiveness (adhesive strength) between the second barrier conductor films (12 and 22) and the first barrier conductor films (11 and 21). As a result, the semiconductor device thus obtained can have improved reliability.

Further, in First Embodiment, the second barrier conductor films (12 and 22) have thereon the third barrier conductor films (13 and 23) made of a conductor material different from that of the second barrier conductor films (12 and 22).

The second barrier conductor films (12 and 22) are made of a conductor material different from that of the third barrier conductor films (13 and 23). If the second barrier conductor films (12 and 22) have a low density, the adhesiveness between the second barrier conductor films (12 and 22) and the third barrier conductor films (13 and 23) decreases and the second barrier conductor films (12 and 22) are likely to separate from the third barrier conductor films (13 and 23).

In First Embodiment, the second barrier conductor films (12 and 22) have an increased density. The high-density second barrier conductor films (12 and 22) have thereon the third barrier conductor films (13 and 23) made of a conductor material different from that of the second barrier conductor films (12 and 22). Even when the second barrier conductor films (12 and 22) and the third barrier conductor films (13 and 23) are made of respectively different conductor materials, the second barrier conductor films (12 and 22) have an increased density and the second barrier conductor films (12 and 22) therefore have high surface flatness so that the adhesiveness (adhesive strength) between the second barrier conductor films (12 and 22) and the third barrier conductor films (13 and 23) can be secured. This means that influenced by the density of the second barrier conductor films (12 and 22) higher than that of the first barrier conductor films (11 and 21), the flatness of the surface (the surface on the side where the third barrier conductor films are formed) of the second barrier conductor films (12 and 22) becomes higher than the flatness of the surface (the surface on the side where the second barrier conductor films are formed) of the first barrier conductor films (11 and 21). The adhesiveness of the third barrier conductor films (13 and 23) can therefore be secured. It is therefore possible to enhance the adhesiveness between the second barrier conductor films (12 and 22) and the third barrier conductor films (13 and 23) and thereby suppress or prevent separation between the second barrier conductor films (12 and 22) and the third barrier conductor films (13 and 23). As a result, the semiconductor device thus obtained can have improved reliability.

Thus, in First Embodiment, the interlayer insulating films (IL1 and IL2) include the porous Low-k films (1 and 4) so that the damage of the porous Low-k films (1 and 4) during formation of the first barrier conductor films (11 and 21) is suppressed or prevented by setting, to a low density, the density of the first barrier conductor films (11 and 21) formed while exposing the porous Low-k films (1 and 4). In consideration that forming, on the low-density first barrier conductor films (11 and 21), a conductor film made of a material of a different kind deteriorates the adhesiveness of the conductor film, high-density second barrier conductor films (12 and 22) made of a material same as that of the low-density first barrier conductor films (11 and 21) are formed on the first barrier conductor film (11 and 21). By forming, on the high-density second barrier conductor films (12 and 22), the third barrier conductor films (13 and 23) made of a material different from that of the second barrier conductor films (12 and 22), the adhesiveness of the second barrier conductor films (12 and 22) and adhesiveness of the third barrier conductor films (13 and 23) can be secured. This makes it possible to suppress or prevent generation of a region, in the buried copper wirings (M1 and M2), where the intermembrane adhesiveness decreases. As a result, the buried copper wirings (M1 and M2) can have improved reliability. The semiconductor device thus obtained can therefore have improved comprehensive reliability.

In the present embodiment, the first barrier conductor films (11 and 21) and the second barrier conductor films (12 and 22) formed on the first barrier conductor films (11 and 21) are made of the same conductor material and at the same time, the density of the first barrier conductor films (11 and 21) is set to lower than that of the second barrier conductor films (12 and 22). This makes it possible to form the first barrier conductor films (11 and 21) as a low density film and the second barrier conductor films (12 and 22) as a high-density film. Since the first barrier conductor films (11 and 21) can be provided as a low density film, the porous Low-k films (1 and 4) included in the interlayer insulating films (IL1 and IL2) can be suppressed or prevented from being damaged during formation of the first barrier conductor films (11 and 21). Since the second barrier conductor films (12 and 22) can be provided as a high-density film, even when the third barrier conductor films (13 and 23) made of a conductor material different from that of the second barrier conductor films (12 and 22) are formed on the second barrier conductor films (12 and 22), adhesiveness of the second barrier conductor films (12 and 22) and adhesiveness of the third barrier conductor films (13 and 23) can be secured. This makes it possible to suppress or prevent the porous Low-k films (1 and 4) included in the interlayer insulating films (IL1 and IL2) from being damaged and at the same time, to suppress or prevent generation of a region, in the buried copper wirings (M1 and M2), where the intermembrane adhesiveness decreases. As a result, the semiconductor device thus obtained can have improved comprehensive reliability.

The thickness of the second barrier conductor films (12 and 22) is preferably greater than that of the first barrier conductor films (11 and 21). In other words, the thickness of the first barrier conductor films (11 and 21) is preferably smaller than that of the second barrier conductor films (12 and 22). This means that in the wiring M1, the thickness of the barrier conductor film 12 is preferably greater than that of the barrier conductor film 11. In the wiring M2, the thickness of the barrier conductor film 22 is preferably greater than that of the barrier conductor film 21. The following is the reason of it.

Described specifically, the first barrier conductor films (11 and 21), the second barrier conductor films (12 and 22), and the third barrier conductor films (13 and 23) have a barrier property (barrier effect) against copper (Cu) and they can function so as to suppress or prevent copper (Cu) in the main conductor films (MC1 and MC2) from diffusing into the interlayer insulating films (IL1 and IL2). When the first barrier conductor films (11 and 21) and the second barrier conductor films (12 and 22) have the same film thickness, the high-density second barrier conductor films (12 and 22) have a barrier property greater than that of the low-density first barrier conductor films (11 and 21). When a sum of the thickness of the first barrier conductor films (11 and 21) and the thickness of the second barrier conductor films (12 and 22) is kept constant, an effect of suppressing or preventing diffusion of copper (Cu) in the main conductor films (MC1 and MC2) into the interlayer insulating films (IL1 and IL2) becomes larger by increasing the thickness of the the second barrier conductor films (12 and 22) than by increasing the thickness of the first barrier conductor films (11 and 21). Increasing the sum of the thickness of the first barrier conductor films (11 and 21) and the thickness of the second barrier conductor films (12 and 22) leads to a reduction in a proportion of the main conductor films (MC1 and MC2) in the wirings (M1 and M2) and moreover, leads to an increase in resistance of the wirings (M1 and M2).

The thickness of the first barrier conductor films (11 and 21) is preferably made smaller than that of the second barrier conductor films (12 and 22). This makes it possible to enhance the barrier property against copper (Cu) in the entire barrier conductor film without increasing the sum of the thickness of the first barrier conductor films (11 and 21) and the thickness of the second barrier conductor films (12 and 22). This can enhance the effect of suppressing or preventing diffusion of copper (Cu) in the main conductor films (MC1 and MC2) into the interlayer insulating films (IL1 and IL2). In addition, since the sum of the thickness of the first barrier conductor films (11 and 21) and the thickness of the second barrier conductor films (12 and 22) can be suppressed from increasing while maintaining the barrier property against copper (Cu), the resistance of the wirings (M1 and M2) can be reduced.

Too small thickness of the first barrier conductor films (11 and 21) may lead to damage of the porous Low-k films (1 and 4) included in the interlayer insulating films (IL1 and IL2) during formation of the high-density second barrier conductor films (12 and 22). The first barrier conductor films (11 and 21) have preferably a thickness of 1 nm or more. In particular, the thickness of the first barrier conductor films (11 and 21) on the porous Low-k films (1 and 4) exposed from the wiring trenches (TR1 and TR2) is preferably 1 nm or more. Such a film thickness can appropriately suppress or prevent the porous Low-k films (1 and 4) included in the interlayer insulating films (IL1 and IL2) from being damaged during formation of the high-density second barrier conductor films (12 and 22) on the first barrier conductor films (11 and 21).

As described above, in order to enhance the barrier property of the entire barrier conductor film against copper (Cu), it is more advantageous to increase the thickness of the second barrier conductor films (12 and 22) than to increase the thickness of the first barrier conductor films (11 and 21). The first barrier conductor films (11 and 21) are desirably not too thick. The thickness of the first barrier conductor films (11 and 21) is particularly preferably within a range of 1 nm or more but not more than 2 nm.

The sum of the thickness of the first barrier conductor films (11 and 21) and the thickness of the second barrier conductor films (12 and 22) is preferably 5 nm or more. This makes it possible to sufficiently maintain the barrier property of the barrier conductor film against copper (Cu). In addition, the adhesiveness (adhesive strength) between the interlayer insulating films (IL1 and IL2) and the wirings (M1 and M2) can be improved.

An excessive increase in the sum of the thickness of the first barrier conductor films (11 and 21) and the thickness of the second barrier conductor films (12 and 22) decreases a proportion of the main conductor films (MC1 and MC2) in the wirings (M1 and M2) accordingly. This results in an increase in wiring resistance. It is therefore more preferred to set the sum of the thickness of the first barrier conductor films (11 and 21) and the thickness of the second barrier conductor films (12 and 22) to fall within a range of from 5 to 15 nm.

In addition, more preferably, the thickness of the third barrier conductor films (13 and 23) is set to fall within a range of from 3 to 10 nm. This makes it possible to maintain the barrier property of the barrier conductor film against copper (Cu) and at the same time, improve the adhesiveness between the interlayer insulating films (IL1 and IL2) and the wirings (M1 and M2). Further, an increase in wiring resistance can be suppressed.

The first barrier conductor films (11 and 21) and the second barrier conductor films (12 and 22) are made of the same material. They preferably have the same crystal structure. This means that it is preferred that the barrier conductor film 11 and the barrier conductor film 12 are made of the same material and at the same time, the barrier conductor film 11 and the barrier conductor film 12 have the same crystal structure. In addition, it is preferred that the barrier conductor film 21 and the barrier conductor film 22 are made of the same material and the barrier conductor film 21 and the barrier conductor film 22 have the same crystal structure. This is because when a two-layer film is formed by stacking, adhesiveness (adhesive strength) between these two films configuring the two-layer film can be maintained more easily when the two films are made of the same material than when the two films are made of respectively different materials and moreover, adhesiveness (adhesive strength) between these two films can be maintained further more easily when the two films have the same crystal structure. In short, when two films of the two-layer film are made of the same material and have the same crystal structure, separation between them due to distortion is not likely to occur more.

Described specifically, the first barrier conductor films (11 and 21) have low density so that they are inferior in surface flatness and adhesiveness of a film formed thereon is likely to decrease. When the second barrier conductor films (12 and 22) formed on the first barrier conductor films (11 and 21) are made of a material and have a crystal structure, each same as those of the first barrier conductor films (11 and 21), adhesiveness between the first barrier conductor films (11 and 21) and the second barrier conductor films (12 and 22) can be enhanced even when the first barrier conductor films (11 and 21) have a low density and low surface flatness. This makes it possible to appropriately suppress or prevent separation between the first barrier conductor films (11 and 21) and the second barrier conductor films (12 and 22).

In the present embodiment, the first barrier conductor films (11 and 21) and the second barrier conductor films (12 and 22) are each preferably made of a tantalum nitride film, because the tantalum nitride film is excellent in barrier property against copper (Cu) and at the same time excellent in adhesiveness to the interlayer insulating films (IL1 and IL2). Comparison between a tantalum nitride film and a tantalum film reveals that the tantalum nitride film has superior adhesiveness to the interlayer insulating films (IL1 and IL2). The tantalum nitride film used as the first barrier conductor films (11 and 21) contiguous to the interlayer insulating films (IL1 and IL2) enables maintenance of the barrier property against copper (Cu) and enhancement of adhesiveness of the first barrier conductor films (11 and 21) to the interlayer insulating films (IL1 and IL2). This makes it possible to appropriately suppress or prevent separation between the first barrier conductor films (11 and 21) and the interlayer insulating films (IL1 and IL2). The second barrier conductor films (12 and 22) and the first barrier conductor films (11 and 21) are made of the same material so that if a tantalum nitride film is used as the first barrier conductor films (11 and 21), it necessarily means using a tantalum nitride film as the second barrier conductor films (12 and 22).

In the present embodiment, the third barrier conductor films (13 and 23) are made of preferably a tantalum film, because the tantalum film is excellent in barrier property against copper (Cu) and at the same time, excellent in adhesiveness to the main conductor films (MC1 and MC2) comprised mainly of copper. Comparison between the tantalum nitride film and the tantalum film reveals that the tantalum film is superior in adhesiveness to the main conductor films (MC1 and MC2) comprised mainly of copper. The tantalum film used as the third barrier conductor films (13 and 23) contiguous to the main conductor films (MC1 and MC2) comprised mainly of copper enables maintenance of the barrier property against copper (Cu) and enhancement of the adhesiveness of the main conductor films (MC1 and MC2) to the third barrier conductor films (13 and 23). This makes it possible to appropriately suppress or prevent separation between the third barrier conductor films (13 and 23) and the main conductor films (MC1 and MC2).

The adhesiveness between the interlayer insulating films (IL1 and IL2) and the barrier conductor films (BR1 and BR2) can therefore be improved more by using a tantalum nitride film superior to a tantalum film in adhesiveness to the interlayer insulating films (IL1 and IL2). The adhesiveness between the main conductor films (MC1 and MC2) and the barrier conductor films (BR1 and BR2) can be improved more by using a tantalum film superior to a tantalum nitride film in adhesiveness to the main conductor films (MC1 and MC2). As a result, both adhesiveness between the interlayer insulating films (IL1 and IL2) and the barrier conductor films (BR1 and BR2) and adhesiveness between the main conductor films (MC1 and MC2) and the barrier conductor films (BR1 and BR2) can be improved appropriately.

Thus, the first barrier conductor films (11 and 21) and the second barrier conductor films (12 and 22) are most preferably a tantalum nitride film, while the third barrier conductor films (13 and 23) are most preferably a tantalum film. Alternatively, as the first barrier conductor films (11 and 21) and the second barrier conductor films (12 and 22), a titanium nitride (TiN) film or a ruthenium nitride (RuN) film can also be used. As the third barrier conductor films (13 and 23), a titanium (Ti) film, a tungsten (W) film, a cobalt (Co) film, a manganese (Mn) film, or a ruthenium (Ru) film, or an alloy film containing two or more of these elements (Ti, W, Co, Mn, and Ru) can also be used.

In the present embodiment, the density of the first barrier conductor films (11 and 21) is set lower than that of the second barrier conductor films (12 and 22). The density of the first barrier conductor films (11 and 21) is preferably from 50 to 90% of the density of the perfect crystal. This means that the density of the first barrier conductor films (11 and 21) is preferably from 50 to 90% of the density of the perfect crystal of a material configuring the first barrier conductor films (11 and 21). Supposing that D₁ means the density of the first barrier conductor films (11 and 21) and D₂ means the density of the perfect crystal of a material configuring the first barrier conductor films (11 and 21), the following formula (1) is preferably satisfied:

0.5≦D₁/D₂≦0.9 (1).

The term “perfect crystal” means a perfect crystal having therein neither crystal defects nor impurities.

The density of the second barrier conductor films (12 and 22) is preferably higher than 90% of the perfect crystal. This means that the density of the second barrier conductor films (12 and 22) is preferably higher than 90% of the density of the perfect crystal of a material configuring the second barrier conductor films (12 and 22). Supposing that D₃ represents a density of the second barrier conductor films (12 and 22) and D₄ represents a density of the perfect crystal of a material configuring the second barrier conductor films (12 and 22), the following formula (2) is preferably satisfied:

0.9<D₃/D₄≦1 (2).

Since the material configuring the first barrier conductor films (11 and 21) and the material configuring the second barrier conductor films (12 and 22) are the same, the density (D₂) of the perfect crystal of the material configuring the first barrier conductor films (11 and 21) and the density (D₄) of the perfect crystal of the material configuring the second barrier conductor films (12 and 22) are equal, which satisfies D₂=D₄.

The density D₂ can also be regarded as a virtual density of the first barrier conductor films (11 and 21) when the first barrier conductor films (11 and 21) are comprised of the perfect crystal. The density D₄ can also be regarded as a virtual density of the second barrier conductor films (12 and 22) when the second barrier conductor films (12 and 22) are comprised of the perfect crystal.

Since the first barrier conductor films (11 and 21) and the second barrier conductor films (12 and 22) are made of the same material, the density of the first barrier conductor films (11 and 21) lower than that of the second barrier conductor films (12 and 22) means the atomic vacancy concentration (vacancy concentration) of the first barrier conductor films (11 and 21) greater than the atomic vacancy concentration (vacancy concentration) of the second barrier conductor films (12 and 22). Accordingly, the atomic vacancy concentration of the barrier conductor film 11 is greater than the atomic vacancy concentration of the barrier conductor film 12 and the atomic vacancy concentration of the barrier conductor film 21 is greater than the atomic vacancy concentration of the barrier conductor film 22.

The “atomic vacancy concentration” as used herein corresponds to a proportion of atomic vacancies to all the lattice points that can be occupied by atoms. The “atomic vacancy” corresponds to a lattice point of a crystal which is expected to have an atom, but does not have it. For example, when there is one atomic vacancy per 10 lattice points on average in a certain film, the atomic vacancy concentration of the film is 10% and the density of the film is 90% of the density of the perfect crystal. A perfect crystal has no atomic vacancy so that the atomic vacancy concentration of the perfect crystal is 0%.

Supposing that D₅ represents the atomic vacancy concentration of the first barrier conductor films (11 and 21), the following formula (3) is satisfied:

D₅=1−D₁/D₂ (3)

Supposing that D₆ represents the atomic vacancy concentration of the second barrier conductor films (12 and 22), the following formula (4) is satisfied:

D₆=1−D₃/D₄ (4).

As described above, the density (D₁) of the first barrier conductor films (11 and 21) is preferably from 50 to 90% of the density (D₂) of the perfect crystal. In other words, the atomic vacancy concentration (D₅) of the first barrier conductor films (11 and 21) is preferably from 10 to 50%. As described above, the density (D₃) of the second barrier conductor films (12 and 22) is preferably 90% or more of the density (D₄) of the perfect crystal. This means that the atomic vacancy concentration (D₆) of the second barrier conductor films (12 and 22) is preferably less than 10%.

Tantalum nitride has a hexagonal crystal structure and its lattice constant is 3.363 angstrom. In First Embodiment, the first barrier conductor films (11 and 21) and the second barrier conductor films (12 and 22) are each preferably a tantalum nitride film. In this case, the tantalum nitride film configuring the first barrier conductor films and the tantalum nitride film configuring the second barrier conductor films each has a hexagonal crystal structure, but the first barrier conductor films have a density lower than that of the second barrier conductor films and therefore, the first barrier conductor films have an atomic vacancy concentration greater than that of the second barrier conductor films. The density (D₂) of the tantalum nitride in perfect crystal form is 14.3 g/cm³. When the tantalum nitride film is Ta₂N, has a hexagonal crystal structure, and has a lattice constant of 3.363 angstrom, the density of the perfect crystal is about 12.6 g/cm³.

It is to be noted that the first barrier conductor films (11 and 21) are preferably made of two or more atomic layers and has preferably an atomic vacancy concentration of from 10 to 50%. When they have such properties, the interlayer insulating films (IL1 and IL2) are completely covered with the first barrier conductor films (11 and 21) on the inner surface of the wiring trenches (TR1 and TR2) and at the same time, in the first barrier conductor films (11 and 21) between the second barrier conductor films (12 and 22) and the interlayer insulating films (IL1 and IL2), an atomic vacancy is substantially present at any planar position. This makes it possible to effectively produce an effect of suppressing or preventing damage of the porous Low-k films (1 and 4) due to the formation of the barrier conductor film. Also from the above standpoint, the thickness of the first barrier conductor films (11 and 21) is preferably 1 nm or more as described above.

The first barrier conductor films (11 and 21) and the second barrier conductor films (12 and 22) are made of the same material but different in density. In the semiconductor device thus manufactured, a difference in density between the first barrier conductor films (11 and 21) and the second barrier conductor films (12 and 22) can be found from the contrast observed using, for example, TEM (transmission electron microscope). For example, contrast in proportion to an atomic amount can be obtained from an HAADF (high-angle annular dark field)-STEM (scanning transmission electron microscope) image. By making use of the HAADF-STEM image, the density of the first barrier conductor films (11 and 21) is found to be lower than that of the second barrier conductor films (12 and 22).

The third barrier conductor films (13 and 23) also have preferably a high density and due to high density, the third barrier conductor films (13 and 23) and the main conductor films (MC1 and MC2) can have therebetween improved adhesiveness (adhesive strength). The third barrier conductor films (13 and 23) are formed on the second barrier conductor films (12 and 22) so that even when the third barrier conductor films (13 and 23) have high density, the porous Low-k films (1 and 4) included in the interlayer insulating films (IL1 and IL2) are not damaged during formation of the third barrier conductor films (13 and 23).

The third barrier conductor films (13 and 23) therefore have a density higher than 90% of the density of the perfect crystal. This means that the third barrier conductor films (13 and 23) have preferably a density higher than 90% of the density of the perfect crystal of a material configuring the third barrier conductor films (13 and 23). Described specifically, supposing that D₇ represents the density of the third barrier conductor films (13 and 23) and D₈ represents the density of the perfect crystal of the material configuring the third barrier conductor films (13 and 23), the following formula (5) is preferably satisfied:

0.9<D₇/D₈≦1 (5)

The density D₈ can also be regarded as a virtual density of the third barrier conductor films (13 and 23) supposing that the third barrier conductor films (13 and 23) are each comprised of a perfect crystal.

Supposing that D₉ represents the atomic vacancy concentration of the third barrier conductor films (13 and 23), the following formula (6) is satisfied:

D₉=1−D₇/D₈ (6)

As described above, the density (D₇) of the third barrier conductor films (13 and 23) is preferably higher than 90% of the density (D₈) of the perfect crystal. This means that the atomic vacancy concentration (D₉) of the third barrier conductor films (13 and 23) is preferably less than 10%.

The density (D₁) of the first barrier conductor films (11 and 21), the density (D₃) of the second barrier conductor films (12 and 22), and the density (D₇) of the third barrier conductor films (13 and 23) preferably satisfy the following formula (7):

D₁/D₂<D₃/D₄ and D₁/D₂<D₇/D₈ (7).

When the above formula (7) is reconstituted from the standpoint of the atomic vacancy concentration, it is desired the atomic vacancy concentration (D₆) of the second barrier conductor films (12 and 22) is greater than the atomic vacancy concentration (D₅) of the first barrier conductor films (11 and 21) (D₆>D₅) and the atomic vacancy concentration (D₉) of the third barrier conductor films (13 and 23) is greater than the atomic vacancy concentration (D₅) of the first barrier conductor films (11 and 21) (D₉>D₅).

The first barrier conductor films (11 and 21) and the second barrier conductor films (12 and 22) are made of the same material, while the third barrier conductor films (13 and 23) are made of a material different from that of the first barrier conductor films (11 and 21) and the second barrier conductor films (12 and 22). The values D₂ and D₄ are therefore equal (D₂=D₄) to each other, but the value D₈ is different from the values D₂ and D₄.

Tantalum has a body-centered cubic crystal structure and its lattice constant is 3.305 angstrom. In First Embodiment, the third barrier conductor films (13 and 23) are preferably a tantalum film and in this case, the tantalum film configuring the third barrier conductor films (13 and 23) has a body-centered steric crystal structure. The density (D₈) of the perfect crystal of tantalum is 16.65 g/cm³.

In Second Embodiment which will be described later, the first barrier conductor films (11 and 21) and the second barrier conductor films (12 and 22) are each preferably a tantalum film. In this case, the tantalum film configuring the first barrier conductor films and the tantalum film configuring the second barrier conductor films each have a body-centered steric crystal structure. The first barrier conductor films however have a density lower than that of the second barrier conductor films and therefore, the first barrier conductor films have an atomic vacancy concentration greater than that of the second barrier conductor films.

Next, a preferable formation process of each of the barrier conductor films will be described.

The second barrier conductor films (12 and 22) are formed preferably by sputtering. Sputtering is excellent in uniformity or quality of a film thus formed. In addition, an impurity other than a material of a film to be formed is not mixed in and a film having a high density can be formed easily. By using sputtering for forming the second barrier conductor films (12 and 22), the second barrier conductor films (12 and 22) can have improved uniformity or quality. In addition, mixing of an unnecessary impurity in the second barrier conductor films (12 and 22) can be easily prevented. Further, the second barrier conductor films (12 and 22) having a high density can be formed easily and appropriately. Moreover, since the high-density second barrier conductor films (12 and 22) have been formed by sputtering, the third barrier conductor films (13 and 23) to be formed on the second barrier conductor films (12 and 22) can have improved adhesiveness more appropriately.

Sputtering is a method of forming a film by depositing, on an underlayer, sputter particles flown from a target so that a physical impact is inevitably applied to the underlayer. The porous Low-k films (1 and 4) configuring the inner surface of the wiring trenches (TR1 and TR2) may be damaged by this impact. In the present embodiment, however, the second barrier conductor films (12 and 22) are formed while having the first barrier conductor films (11 and 21) on the inner surface of the wiring trenches (TR1 and TR2), in other words, without exposing the porous Low-k films (1 and 4) from the wiring trenches (TR1 and TR2). Even when the second barrier conductor films (12 and 22) are formed by sputtering, the porous Low-k films (1 and 4) included in the interlayer insulating films (IL1 and IL2) can be suppressed or prevented from being damaged during formation of the second barrier conductor films (12 and 22) by sputtering.

For the formation of the first barrier conductor films (11 and 21), sputtering or ALD is preferably used. Sputtering is advantageous over ALD for the formation of a high-density film (namely, a dense film), but the first barrier conductor films (11 and 21) are not required to have a high density so that either sputtering or ALD can be used for the formation of the first barrier conductor films (11 and 21). Using sputtering for the formation of the first barrier conductor films (11 and 21) and using ALD for the formation of the first barrier conductor films (11 and 21) have the following advantages, respectively.

Using sputtering for the formation of the first barrier conductor films (11 and 21) means that the same material and the same process (sputtering) are used for the formation of the first barrier conductor films (11 and 21) and the second barrier conductor films (12 and 22). In this case, time spent for the step of forming the first barrier conductor films (11 and 21) and the step of forming the second barrier conductor films (12 and 22) can be reduced, leading to a reduction in the manufacture time of a semiconductor device. In addition, it contributes to improvement in through-put of the semiconductor device. Further, the same sputtering apparatus can be used for the formation of the first barrier conductor films (11 and 21) and the second barrier conductor films (12 and 22). This decreases the number of apparatuses necessary for the manufacture of the semiconductor device. The step of forming the first barrier conductor films (11 and 21) and the step of forming the second barrier conductor films (12 and 22) can be performed successively while using the same sputtering apparatus and in this case, unloading of a semiconductor wafer (semiconductor substrate SB) from a treatment chamber (chamber CM) of a sputtering apparatus is not necessary between the step of forming the first barrier conductor films (11 and 21) and the step of forming the second barrier conductor films (12 and 22). This facilitates the manufacturing steps of the semiconductor device, decreases the manufacture time of the semiconductor device, and improves the through-put. Moreover, using sputtering for the formation of the first barrier conductor films (11 and 21) is likely to prevent mixing of an unnecessary impurity into the first barrier conductor films (11 and 21).

Sputtering is a method of forming a film by depositing, on an underlayer, sputter particles flown from a target. A physical impact is inevitably applied to the underlayer and the porous Low-k films (1 and 4) configuring the inner surface of the wiring trenches (TR1 and TR2) may be damaged by this impact. In First Embodiment, however, since the first barrier conductor films (11 and 21) have a reduced density, even when the first barrier conductor films (11 and 21) are formed by sputtering, the porous Low-k films (1 and 4) included in the interlayer insulating films (IL1 and IL2) can be prevented from being damaged by it during formation of the first barrier conductor films (11 and 21).

On the other hand, ALD can form a film without applying a physical impact on the underlayer. Compared with sputtering, ALD is unlikely to cause damage on an underlayer formed below an intended film. When the first barrier conductor films (11 and 21) are formed by ALD, the porous Low-k films (1 and 4) included in the interlayer insulating films (IL1 and IL2) can be suppressed or prevented from being damaged more appropriately during formation of the first barrier conductor films (11 and 21).

From the standpoint of shortening a manufacturing time or improving a through-put, sputtering is superior in forming the first barrier conductor films (11 and 21). From the standpoint of suppressing the porous Low-k films (1 and 4) from damage as much as possible, on the other hand, ALD is superior in forming the first barrier conductor films (11 and 21).

Sputtering is suited for the formation of the third barrier conductor films (13 and 23). This contributes to improvement in uniformity or quality of the third barrier conductor films (13 and 23). In addition, this method facilitates prevention of mixing of an unnecessary impurity in the third barrier conductor films (13 and 23). Further, by using this method, the third barrier conductor films (13 and 23) with a high density can be formed easily and appropriately. The high-density third barrier conductor films (13 and 23) can be formed by sputtering so that the main conductor films (MC1 and MC2) formed on the third barrier conductor films (13 and 23) can have improved adhesiveness more appropriately.

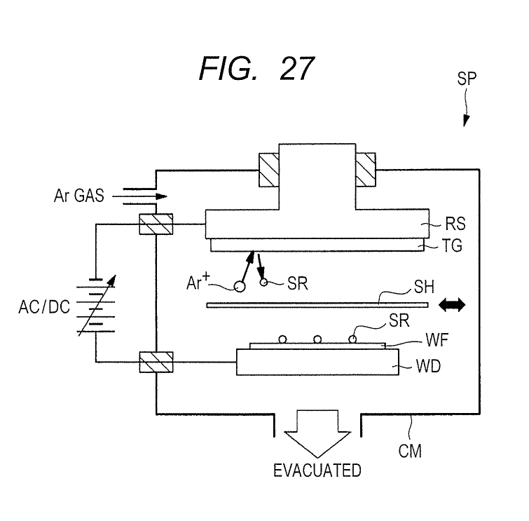

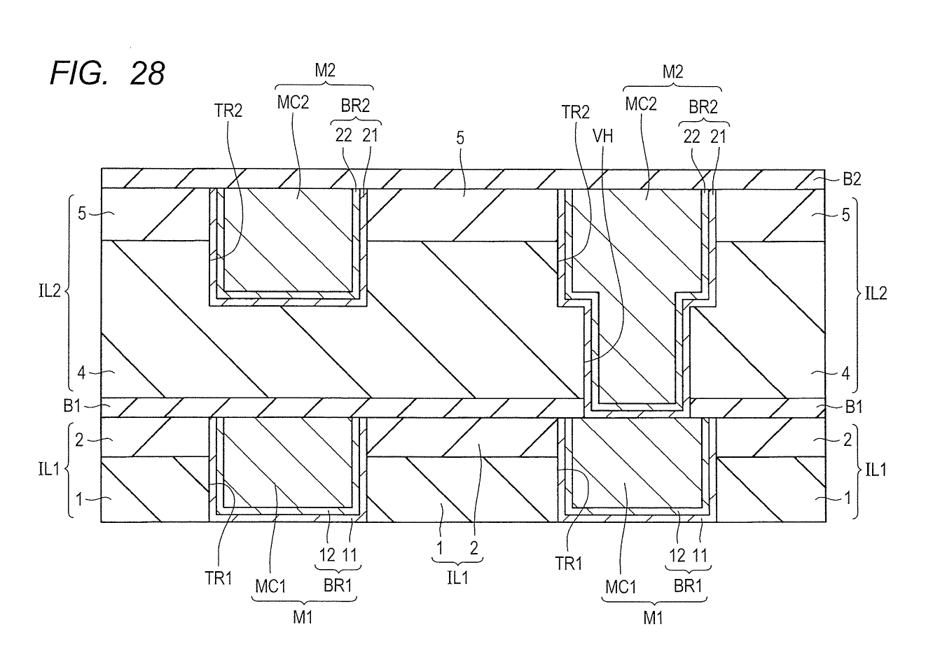

FIG. 27 is an explanatory view showing one example of a sputtering apparatus to be used for the formation of the barrier conductor films.

In a sputtering apparatus SP shown in FIG. 27, a semiconductor wafer WF (corresponding to the semiconductor substrate SB) is placed on a pedestal WD in a chamber (treatment room) CM and a target TG for film formation is placed at a position facing the semiconductor wafer WF. The target TG is attached to a cooling system RS. A shielding shutter SH is placed between the semiconductor wafer WF and the target TG. When a film is formed on the semiconductor wafer WF, the shutter SH is transferred to a position other than that between the semiconductor wafer WF and the target TG to allow deposition of sputter particles SR flown from the target TG on the semiconductor wafer WF.

During film formation on the semiconductor wafer WF, a sputtering gas such as argon gas is introduced into an evacuated chamber CM and a high voltage is applied to between the semiconductor wafer WF and the target TG. An argon ion (Art) thus generated is allowed to collide with the target TG and sputter particles SR made of a target material emitted from the target TH are deposited on the semiconductor wafer SF. A film can therefore be formed on the semiconductor wafer WF. A nitrogen gas as well as an argon gas may be introduced into the chamber.

When the first barrier conductor films (11 and 21) and the second barrier conductor films (12 and 22) are each formed by sputtering, the density of the films to be formed can be controlled by the pressure (pressure in the chamber CM) during formation. Described specifically, at the time of forming films by sputtering, the resulting films have an increased density with a decrease in the pressure in the chamber CM, while the resulting films tend to have a reduced density with an increase in the pressure in the chamber CM. By making use of such a tendency and making the pressure in the chamber CM during formation of the first barrier conductor films (11 and 21) greater than the pressure in the chamber CM during formation of the second barrier conductor films (12 and 22), the first barrier conductor films (11 and 21) can have a density lower than that of the second barrier conductor films (12 and 22).

As one example, during formation of a tantalum nitride film configuring the first barrier conductor films (11 and 21) by sputtering, the pressure in the chamber CM can be adjusted to from about 1 to 10 mTorr, the radio frequency (RF) power to be applied to the semiconductor wafer WF can be adjusted to from about 0 to 1000 W, and the DC bias power of the target TG can be adjusted to from about 1000 to 15000 W. During formation of a tantalum nitride film configuring the second barrier conductor films (12 and 22) by sputtering, the pressure in the chamber CM can be adjusted to from about 0.1 to 1 mTorr, the radio frequency (RF) power to be applied to the semiconductor wafer WF can be adjusted to from about 0 to 1000 W, and the DC bias power of the target TG can be adjusted to from about 1000 to 15000 W. Under the above conditions, the first barrier conductor films (11 and 21) comprised of a low-density tantalum nitride film and the second barrier conductor films (12 and 22) comprised of a high-density tantalum nitride film can be formed.

When the first barrier conductor films (11 and 21) and the second barrier conductor films (12 and 22) are both formed by sputtering, the density of films to be formed can be controlled not by pressure but by applied power. For example, the first barrier conductor films (11 and 21) are formed by adjusting the DC bias power of the target TG to from 100 to 1000 W without applying a radio frequency power to the semiconductor wafer WF and the second barrier conductor films (12 and 22) are formed by adjusting the power to be higher than above (for example, adjusting the DC bias power of the target TG to from 1000 to 20000 W and the refractory power of the semiconductor wafer WF to from 0 to 1000 W). Under the above conditions, the first barrier conductor films (11 and 21) can have a density lower than that of the second barrier conductor films (12 and 22). The density of each of the first barrier conductor films (11 and 21) and the second barrier conductor films (12 and 22) can be controlled by a pressure and power applied to each of the semiconductor wafer and the target TG.

When the first barrier conductor films (11 and 21) are formed by ALD, on the other hand, the density of the first barrier conductor films (11 and 21) can be controlled as described below. Described specifically, in ALD, a film is formed by repeating a step of allowing atoms to adsorb onto an underlayer, a step of reacting the atoms thus adsorbed, and a step of eliminating unnecessary atoms and thereby stacking atomic layers. The film thus formed can have a reduced density because the number of atoms adsorbed decreases with a decrease in time spent for the step of allowing atoms to adsorb.

### Second Embodiment

FIG. 28 is a fragmentary cross-sectional view of a semiconductor device of Second Embodiment and it corresponds to FIG. 1 of First Embodiment.

The semiconductor device of Second Embodiment is different from that of First Embodiment in the following point.

In First Embodiment, the barrier conductor film BR1 is a stacked film comprised of the barrier conductor film 11 formed on the inner surface (the bottom surface and the side wall) of the wiring trench TR1, the barrier conductor film 12 formed on the barrier conductor film 11, and the barrier conductor film 13 formed on the barrier conductor film 12. The barrier conductor film BR2 is a stacked film comprised of the barrier conductor film 21 formed on the inner surface (the bottom surface and the side wall) of the wiring trench TR2 and the via hole VH, the barrier conductor film 22 formed on the barrier conductor film 21, and the barrier conductor film 23 formed on the barrier conductor film 22.

In Second Embodiment, on the other hand, a barrier conductor film BR1 is a stacked film of a barrier conductor film 11 formed on the inner surface (the bottom surface and the side wall) of the wiring trench TR1 and a barrier conductor film 12 formed on the barrier conductor film 11. A barrier conductor film BR2 is a stacked film of a barrier conductor film 21 formed on the inner surface (the bottom surface and the side wall) of the wiring trench TR2 and the via hole VH and a barrier conductor film 22 formed on the barrier conductor film 21.

In short, Second Embodiment has no film corresponding to the barrier conductor films 13 and 23. Second Embodiment has films corresponding to the first barrier conductor films (11 and 21) and the second barrier conductor films (12 and 22) of First Embodiment, but has no film corresponding to the third barrier conductor films (13 and 23).

In First Embodiment, therefore, the barrier conductor film 13 has thereon the main conductor film MC1 and the barrier conductor film 23 has thereon the main conductor film MC2, while in Second Embodiment, the barrier conductor film 12 has thereon a main conductor film MC1 and the barrier conductor film 22 has thereon a main conductor film MC2. In First Embodiment, therefore, the main conductor film MC1 and the barrier conductor film 12 have therebetween the barrier conductor film 13 and the main conductor film MC2 and the barrier conductor film 22 have therebetween the barrier conductor film 23. In Second Embodiment, on the other hand, the main conductor film MC1 is contiguous to the barrier conductor film 12 and the main conductor film MC2 is contiguous to the barrier conductor film 22.

First Embodiment and Second Embodiment are in common in that the barrier conductor film 11 and the barrier conductor film 12 are made of the same conductor material and the barrier conductor film 11 has a density lower than that of the barrier conductor film 12. In addition, First Embodiment and Second Embodiment are in common in that the barrier conductor film 21 and the barrier conductor film 22 are made of the same conductor material and the barrier conductor film 21 has a density lower than that of the barrier conductor film 22.

In First Embodiment, however, the barrier conductor films 11, 12, 21, and 22 are each preferably made of a tantalum nitride film, while in Second Embodiment, the barrier conductor films 11, 12, 21, and 22 are each preferably made of a tantalum (Ta) film. Thickness and formation method of the barrier conductor films 11, 12, 21, and 22 in Second Embodiment are similar to those of First Embodiment.

Another configuration of the semiconductor device of Second Embodiment is almost similar to that of the semiconductor device of First Embodiment so that an overlapping description is omitted here.

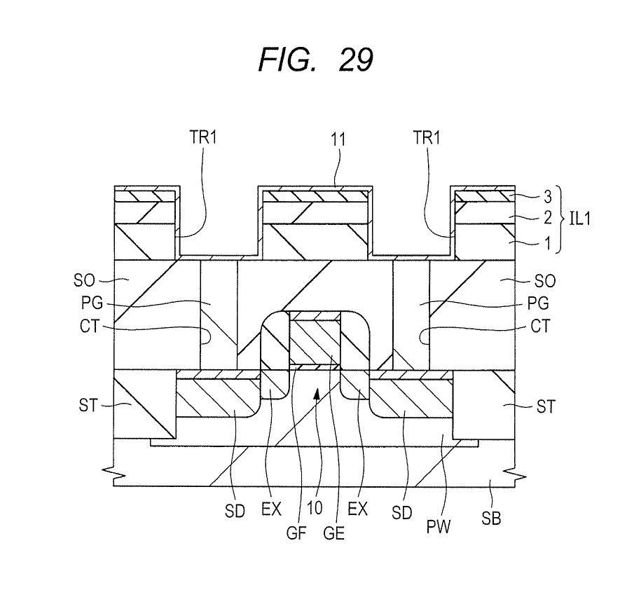

Next, manufacturing steps of the semiconductor device of Second Embodiment will be described referring to FIGS. 29 to 37. FIGS. 29 to 37 are fragmentary cross-sectional views of the semiconductor device of Second Embodiment during manufacturing steps thereof.

The manufacturing steps of Second Embodiment are similar to those of First Embodiment until the structure of FIG. 5 is obtained so that an overlapping description of them is omitted here.

After obtaining the structure of FIG. 5 in a manner similar to that of First Embodiment, a barrier conductor film 11 is formed on the main surface of the semiconductor substrate SB, in other words, on the interlayer insulating film IL1 including the inner surface (the bottom surface and the side wall) of the wiring trench TR1, as shown in FIG. 29. In Second Embodiment, the barrier conductor film 11 is preferably a tantalum (Ta) film and sputtering or ALD is suited for its formation.

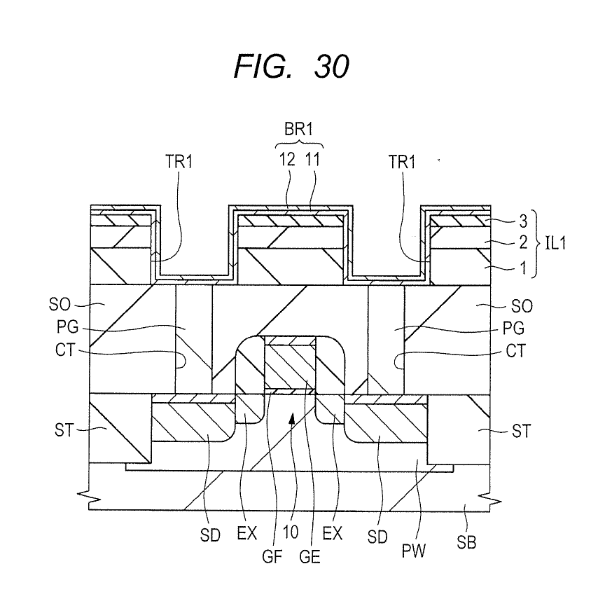

Next, as shown in FIG. 30, a barrier conductor film 12 is formed on the barrier conductor film 11. The barrier conductor film 12 is made of a material same as that of the barrier conductor film 11 and it is preferably a tantalum (Ta) film. Sputtering is suited for the formation of the barrier conductor film 12. The barrier conductor film 11 and the barrier conductor film 12 are made of a conductive material of the same kind (here, tantalum), but the barrier conductor film 12 has a density higher than that of the barrier conductor film 11.

As a result, the interlayer insulating film IL1 including the inner surface (the bottom surface and the side wall) of the wiring trench TR1 has thereon the barrier conductor film BR1 which is a stacked film of the barrier conductor film 11 and the barrier conductor film 12 on the barrier conductor film 11. At this stage, the wiring trench TR1 has remained unfilled. In Second Embodiment, a film corresponding to the barrier conductor film 13 of First Embodiment is not formed.

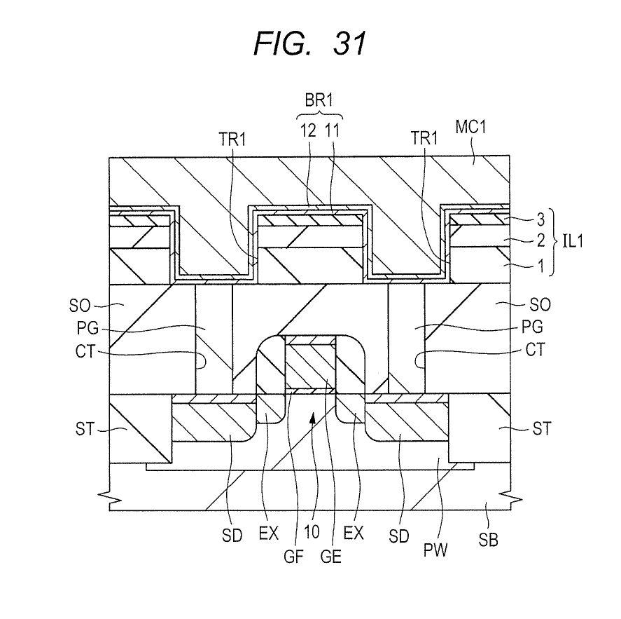

Next, as shown in FIG. 31, a main conductor film MC1 comprised mainly of copper is formed on the barrier conductor film BR1, in other words, on the barrier conductor film 12 serving as a top layer of the barrier conductor film BR1, so as to fill the wiring trench TR1 with the film. The configuration and formation method of the main conductor film MC1 in Second Embodiment are similar to those of First Embodiment.

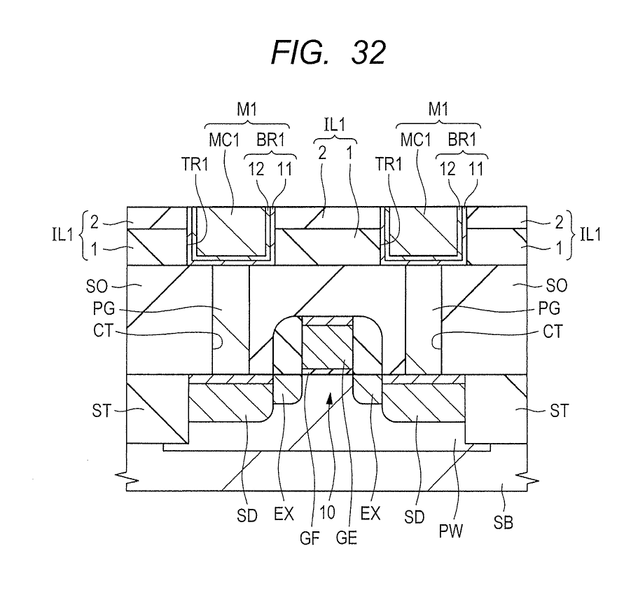

Next, as shown in FIG. 32, a wiring M1 is formed by removing an unnecessary portion of the main conductor film MC1 and the barrier conductor films BR1 (11 and 12) outside the wiring trench TR1 by polishing treatment using CMP while leaving the other portion of the main conductor film MC1 and the barrier conductor films BR1 (11 and 12) in the wiring trench TR1. The above polishing treatment will hereinafter be called “polishing treatment of FIG. 32”. The wiring M1 is comprised of the main conductor film MC1 and the barrier conductor films BR1 (11 and 12) buried in the wiring trench TR1. The polishing treatment of FIG. 32 exposes the upper surface of the interlayer insulating film IL1 and the upper surface of the wiring M1 so that the exposed upper surface of the interlayer insulating film IL1 and the exposed upper surface of the wiring M1 configure an almost flat surface.

FIG. 32 shows the exposed upper surface of the SiOC film 2 after removal of the silicon oxide film 3 by the polishing treatment of FIG. 32. Even by the polishing treatment of FIG. 32, the silicon oxide film 3 may remain in layer form in Second Embodiment similar to First Embodiment.

The wiring M1 can be formed as described above.

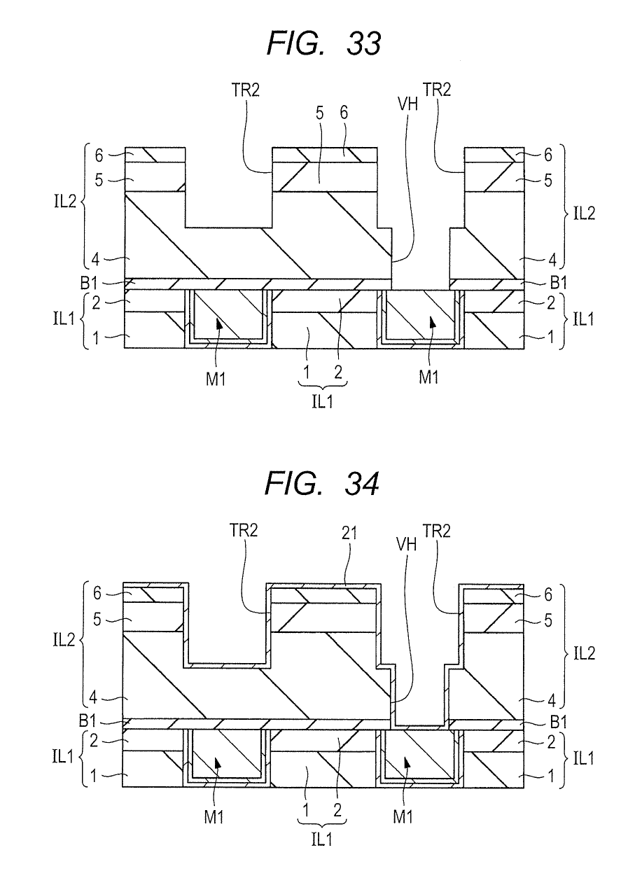

Steps similar to FIGS. 11 to 18 are then performed to obtain a structure of FIG. 33 corresponding to FIG. 18. Also in Second Embodiment similar to First Embodiment, a barrier insulating film B1 and an interlayer insulating film IL2 are formed on the interlayer insulating film IL1 having therein the wiring M1 and a wiring trench TR2 and a via hole VH are formed in the stacked film comprised of the interlayer insulating film IL2 and the barrier insulating film B1.

Next, as shown in FIG. 34, a barrier conductor film 21 is formed on the main surface of the semiconductor substrate SB, in other words, on the interlayer insulating film IL2 including the inner surface (the bottom surface and the side wall) of the wiring trench TR2 and the via hole VH. In Second Embodiment, the barrier conductor film 21 is preferably a tantalum (Ta) film and it can be formed preferably by sputtering or ALD.

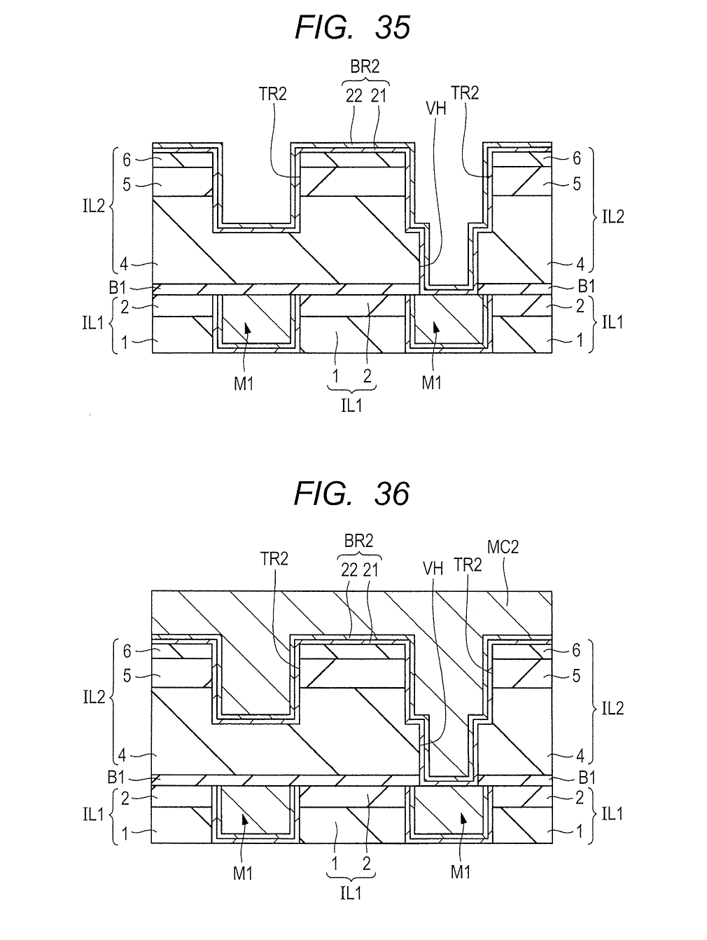

Next, as shown in FIG. 35, a barrier conductor film 22 is formed on the barrier conductor film 21. The barrier conductor film 22 is made of a conductive material same as that of the barrier conductor film 21 and it is preferably a tantalum (Ta) film. The barrier conductor film 22 can be formed preferably by sputtering. The barrier conductor film 21 and the barrier conductor film 22 are made of a conductive material of the same kind (here, tantalum), but the barrier conductor film 22 has a density higher than that of the barrier conductor film 21.

As a result, the interlayer insulating film IL2 including the inner surface (the bottom surface and the side surface) of the wiring trench TR2 and the via hole VH has thereon the barrier conductor film BR2 which is a stacked film of the barrier conductor film 21 and the barrier conductor film 22 on the barrier conductor film 21. At this stage, the wiring trench TR2 and the via hole VH have remained unfilled. In Second Embodiment, a film corresponding to the barrier conductor film 23 of First Embodiment is not formed.

Next, as shown in FIG. 36, a main conductor film MC2 comprised mainly of copper is formed on the barrier conductor film BR2, in other words, on the barrier conductor film 22 serving as a top layer of the barrier conductor film BR2, so as to fill the wiring trench TR2 and the via hole VH with the film. The configuration and formation method of the main conductor film MC2 in Second Embodiment are similar to those of First Embodiment.

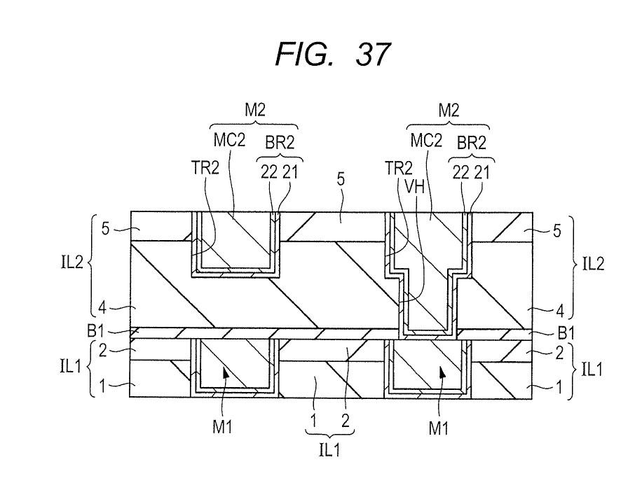

Next, as shown in FIG. 37, a wiring M2 is formed by removing an unnecessary portion of the main conductor film MC2 and the barrier conductor films BR2 (21 and 22) outside the wiring trench TR2 and the via hole VH by polishing treatment using CMP while leaving the other portion of the main conductor film MC1 and the barrier conductor films BR2 (21 and 22) in the wiring trench TR2 and the via hole VH. The above polishing treatment will hereinafter be called “polishing treatment of FIG. 37”. The wiring M2 is comprised of the main conductor film MC2 and the barrier conductor films BR2 (21 and 12) buried in the wiring trench TR2. The via portion of the wiring M2 buried in the via hole VH is integral with the wiring M2 buried in the wiring trench TR2. The polishing treatment of FIG. 37 exposes the upper surface of the interlayer insulating film IL2 and the upper surface of the wiring M2 so that the exposed upper surface of the interlayer insulating film IL2 and the exposed upper surface of the wiring M2 configure an almost flat surface.

FIG. 37 shows the exposed upper surface of the SiOC film 5 after removal of the silicon oxide film 6 by the polishing treatment of FIG. 37. Even by the polishing treatment of FIG. 37, the silicon oxide film 6 may remain in layer form in Second Embodiment similar to First Embodiment.

The wiring M2 can be formed as described above.

Steps of Second Embodiment thereafter are similar to those of First Embodiment so that illustration and overlapping description of them are omitted here.

Second Embodiment has films corresponding to the first barrier conductor films (11 and 21) and the second barrier conductor films (12 and 22) of First Embodiment, but does not have films corresponding to the third barrier conductor film (13 and 23).

First Embodiment and Second Embodiment are however in common in that the first barrier conductor films (11 and 21) and the second barrier conductor films (12 and 22) are made of the same conductor material and the first barrier conductor films (11 and 21) have a density lower than that of the second barrier conductor films (12 and 22). Advantages described in First Embodiment can also be obtained by Second Embodiment.

Briefly speaking, also in Second Embodiment, the interlayer insulating films (IL1 and IL2) include the porous Low-k films (1 and 4) so that the porous Low-k films (1 and 4) can be suppressed or prevented from damage during formation of the first barrier conductor films (11 and 21) by forming the first barrier conductor films (11 and 21) as a low density film. This makes it possible to suppress or prevent the semiconductor device from having reduced reliability due to the damage of the porous Low-k films (1 and 4). In consideration that forming, on the low-density first barrier conductor films (11 and 21), a conductor film made of a material of a different kind deteriorates the adhesiveness of the conductor film, the high-density second barrier conductor films (12 and 22) made of a material same as that of the first barrier conductor films (11 and 21) is formed on the low-density first barrier conductor films (11 and 21). By forming the main conductor films (MC1 and MC2) comprised mainly of copper on this high-density second barrier conductor films (12 and 22), adhesiveness of the second barrier conductor films (12 and 22) and adhesiveness of the main conductor films (MC1 and MC2) can be maintained. This makes it possible to suppress or prevent appearance of a region where the adhesiveness between films decreases so that the buried copper wirings (M1 and M2) can have improved reliability. As a result, the semiconductor device can have improved comprehensively reliability.

In First Embodiment, however, an increase in the density of the second barrier conductor films (12 and 22) improves adhesiveness between the second barrier conductor films (12 and 22) and the third barrier conductor films (13 and 23). In Second Embodiment, on the other hand, an increase in the density of the second barrier conductor films (12 and 22) improves adhesiveness between the second barrier conductor films (12 and 22) and the main conductor films (MC1 and MC2).

Second Embodiment has films corresponding to the first barrier conductor films (11 and 21) and the second barrier conductor films (12 and 22) of First Embodiment but does not have films corresponding to the third barrier conductor films (13 and 23). In Second Embodiment compared with First Embodiment, therefore, the thickness of the barrier conductor films BR1 and BR2 can be decreased easily. By decreasing the thickness of the barrier conductor films BR1 and BR2, a proportion of the barrier conductor films (BR1 and BR2) in the wirings (M1 and M2) can be decreased, which leads to an increase in a proportion of the main conductor films (MC1 and MC2) in the wirings (M1 and M2) and therefore, a reduction in wiring resistance. In addition, a decrease in the thickness of the barrier conductor films BR1 and BR2 brings about the advantage that the main conductor films (MC1 and MC2) can be buried more easily because the size of an opening from which the main conductor films (MC1 and MC2) are buried becomes greater.

Second Embodiment is advantageous in reduction in wiring resistance and improvement in filling of the main conductor films (MC1 and MC2) because the barrier conductor films (BR1 and BR2) can be thinned in the second embodiment having no films corresponding to the third barrier conductor films (13 and 23).

In First Embodiment, on the other hand, the barrier conductor films (BR1 and BR2) of the wirings (M1 and M2) have not only the first barrier conductor films (11 and 21) and the second barrier conductor films (12 and 22) but also the third barrier conductor films (13 and 23) and the third barrier conductor films (13 and 23) are sandwiched between the main conductor films (MC1 and MC2) and the second barrier conductor films (12 and 22).

In First Embodiment, the first barrier conductor films (11 and 21) contiguous to the interlayer insulating films (IL1 and IL2) and the third barrier conductor films (13 and 23) contiguous to the main conductor films (MC1 and MC2) comprised mainly of copper can therefore be made of respectively different materials. In First Embodiment, therefore, a material film excellent in adhesiveness to the interlayer insulating films (IL1 and IL2) can be used as the first barrier conductor films (11 and 21) and a material film excellent in the adhesiveness to the main conductor films (MC1 and MC2) comprised mainly of copper can be used as the third barrier conductor films (13 and 23). For example, a tantalum nitride film is particularly excellent in adhesiveness to the interlayer insulating films (IL1 and IL2) and a tantalum film is particularly excellent in adhesiveness to the main conductor films (MC1 and MC2) comprised mainly of copper. In First Embodiment, therefore, using a tantalum nitride film as the first barrier conductor films (11 and 21) and the second barrier conductor films (12 and 22) can improve adhesiveness between the barrier conductor films (BR1 and BR2) and the interlayer insulating films (IL1 and IL2) further. Using a tantalum film as the third barrier conductor films (13 and 23) can improve adhesiveness between the barrier conductor films (BR1 and BR2) and the main conductor films (MC1 and MC2) further.

First Embodiment is therefore advantageous in that both the adhesiveness between the barrier conductor films (BR1 and BR2) and the interlayer insulating films (IL1 and IL2) and the adhesiveness between the barrier conductor films (BR1 and BR2) and the main conductor films (MC1 and MC2) can be improved more appropriately.

In Second Embodiment, a tantalum film is most preferred as the first barrier conductor films (11 and 21) and the second barrier conductor films (12 and 22). Alternatively, a titanium (Ti) film, a ruthenium (Ru) film, a tungsten (W) film, a cobalt (Co) film, or a manganese (Mn) film, or an alloy film containing two or more of elements (Ti, Ru, W, Co, and Mn) may be used as the first barrier conductor films (11 and 21) and the second barrier conductor films (12 and 22).

When a plurality of wiring layers is formed on the semiconductor substrate SB and the wirings (M1 and M2) of First Embodiment or Second Embodiment are applied to one or more of them, the one or more wiring layers can obtain the advantage described in First Embodiment or Second Embodiment. When a plurality of wiring layers is formed on the semiconductor substrate SB, it is preferred to apply the wirings (M1 and M2) of First Embodiment or Second Embodiment to copper wirings buried in the interlayer insulating films including the porous Low-k film.

In one semiconductor device, the wiring layer having therein the wirings (M1 and M2) of First Embodiment and the wiring layer having therein the wirings (M1 and M2) of Second Embodiment may be placed in combination.

When the semiconductor substrate SB has thereon a plurality of wiring layers, the wirings (M1 and M2) of First Embodiment or Second Embodiment are not necessarily be applied to copper wirings buried in the interlayer insulating films not including the porous Low-k film. For example, the wirings (M101 and M102) of First Investigation Example of FIG. 25 may be applied.

Inventions made by the present inventors have been described specifically based on the embodiments thereof. It is needless to say that the inventions are not limited to or by them but can be changed variously without departing from the gist of the invention.

What is claimed is:

1. A semiconductor device, comprising:
a semiconductor substrate;
an interlayer insulating film formed over the semiconductor substrate; and
a wiring buried in a wiring trench in the interlayer insulating film,
wherein the wiring comprises:
a first barrier conductor film formed over the bottom surface and side wall of the wiring trench;
a second barrier conductor film formed over the first barrier conductor film; and
a main conductor film formed over the second barrier conductor film and has copper as a main component,
wherein the interlayer insulating film includes a porous low-dielectric-constant insulating film,
wherein the first barrier conductor film and the second barrier conductor film has the same conductor material, and
wherein the first barrier conductor film has a density lower than that of the second barrier conductor film.

2. The semiconductor device according to claim 1,
wherein the second barrier conductor film has a thickness greater than that of the first barrier conductor film.

3. The semiconductor device according to claim 1,
wherein the first barrier conductor film and the second barrier conductor film have the same crystal structure.

4. The semiconductor device according to claim 1,
wherein the wiring further comprises a third barrier conductor film sandwiched between the second barrier conductor film and the main conductor film, and
wherein the third barrier conductor film has a conductor material different from that of the first barrier conductor film and the second barrier conductor film.

5. The semiconductor device according to claim 4,
wherein the first barrier conductor film and the second barrier conductor film each have a tantalum nitride film.

6. The semiconductor device according to claim 5,
wherein the third barrier conductor film has a tantalum film.

7. The semiconductor device according to claim 1,
wherein the first barrier conductor film and the second barrier conductor film each have a tantalum film.

8. The semiconductor device according to claim 1,
wherein the density of the first barrier conductor film is from 50 to 90% of a density of a perfect crystal of the material configuring the first barrier conductor film.

9. The semiconductor device according to claim 8,
wherein the density of the second barrier conductor film is more than 90% of a density of a perfect crystal of the material configuring the second barrier conductor film.

10. A method of manufacturing a semiconductor device, comprising the steps of:
(a) forming, over a semiconductor substrate, an interlayer insulating film including a porous low-dielectric-constant insulating film;
(b) forming a wiring trench in the interlayer insulating film;
(c) forming a first barrier conductor film over the interlayer insulating film including a bottom surface and a side wall of the wiring trench;
(d) forming a second barrier conductor film over the first barrier conductor film;
(e) forming, over the second barrier conductor film, a main conductor film having copper as a main component so as to fill the wiring trench therewith; and
(f) forming a wiring buried in the wiring trench by removing the main conductor film, the second barrier conductor film, and the first barrier conductor film outside the wiring trench and leaving the main conductor film, the second barrier conductor film, and the first barrier conductor film in the ing trench,
wherein the first barrier conductor film and the second barrier conductor film have the same conductor material, and
wherein the first barrier conductor film has a density lower than that of the second barrier conductor film.

11. The method of manufacturing a semiconductor device according to claim 10,
wherein in the step (c), sputtering is used for the formation of the first barrier conductor film, and
wherein in the step (d), sputtering is used for the formation of the second barrier conductor film.

12. The method of manufacturing a semiconductor device according to claim 10,
wherein in the step (c), ALD is used for the formation of the first barrier conductor film, and
wherein in the step (d), sputtering is used for the formation of the second barrier conductor film.

13. The method of manufacturing a semiconductor device according to claim 10,
wherein the second barrier conductor film has a thickness greater than that of the first barrier conductor film.

14. The method of manufacturing a semiconductor device according to claim 10,
wherein the first barrier conductor film and the second barrier conductor film have the same crystal structure.

15. The method of manufacturing a semiconductor device according to claim 10, further comprising, after the step (d) but before the step (e), a step of:
(d1) forming a third barrier conductor film over the second barrier conductor film,
wherein the third barrier conductor film has a conductor material different from that of the first barrier conductor films and the second barrier conductor film,
wherein in the step (e), the main conductor film is formed over the third barrier conductor film so as to fill the wiring trench, and
wherein in the step (f), the wiring buried in the wiring trench is formed by removing the main conductor film, the third barrier conductor film, the second barrier conductor film, and the first barrier conductor film outside the wiring trench and leaving the main conductor film, the third barrier conductor film, the second barrier conductor film, and the first barrier conductor film in the wiring trench.

16. The method of manufacturing a semiconductor device according to claim 15,
wherein the first barrier conductor film and the second barrier conductor film each have a tantalum nitride film, and
wherein the third barrier conductor film has a tantalum film.

17. The method of manufacturing a semiconductor device according to claim 10,
wherein the first barrier conductor film and the second barrier conductor film each have a tantalum film.

18. The method of manufacturing a semiconductor device according to claim 10,
wherein a density of the first barrier conductor film is from 50 to 90% of a density of a perfect crystal of the material configuring the first barrier conductor films.

19. The method of manufacturing a semiconductor device according to claim 18,
wherein the density of the second barrier conductor film is more than 90% of a density of a perfect crystal of the material configuring the second barrier conductor film.
